(19) United States
(12) Patent Application Publication
(10) Pub. No.: US 2026/0136970 A1
(43) Pub. Date: May 14, 2026

(54) FULLY MOLDED BRIDGE INTERPOSER AND METHOD OF MAKING THE SAME

(71) Applicant: Deca Technologies USA, Inc., Tempe, AZ (US)

(72) Inventors: Timothy L. OLSON, Phoenix, AZ (US); Craig BISHOP, Scottsdale, AZ (US); Clifford SANDSTROM, Richfield, MN (US)

(21) Appl. No.: 19/441,030

(22) Filed: Jan. 6, 2026

Related U.S. Application Data
(63) Continuation-in-part of application No. 19/291,459, filed on Aug. 5, 2025.
Application No. 19/291,459 is a continuation of application No. 18/085,397, filed on Dec. 20, 2022, now Pat. No. 12,381,154.
Application No. 18/085,397 is a continuation of application No. 17/581,704, filed on Jan. 21, 2022, now Pat. No. 11,538,759.
(60) Provisional application No. 63/141,945, filed on Jan. 26, 2021.

(51) Int. Cl. H10W 70/65; H10W 70/05; H10W 70/60; H10W 70/685; H10W 72/20; H10W 90/00

(52) U.S. Cl. CPC H10W 70/65; G03F 7/0045; G03F 7/0382; G03F 7/0397; G03F 7/40; H05K 1/115; H10W 70/05; H10W 70/095; H10W 70/611; H10W 70/685; H10W 90/00; H10W 90/401; H10W 90/701; H10W 70/60; H10W 70/614; H10W 72/252; H10W 90/722; H10W 90/724

(57) ABSTRACT

A semiconductor assembly includes a bridge component without vias extending through the bridge component. The bridge component includes one or more interconnect layers over a frontside of the bridge and an outermost interconnect layer coupled to conductive studs. Conductive vertical interconnects are in a periphery of the assembly with an encapsulant on five sides of the bridge component, on sides of the conductive studs, and on sides of the conductive vertical interconnects that leave ends of the conductive studs and ends of the conductive vertical interconnects coplanar with top and bottom surfaces of the encapsulant. A frontside build-up interconnect structure is over the conductive studs and couple to first ends of the conductive vertical interconnects. The frontside build-up interconnect includes first pads at a first pitch within a footprint of the bridge component and second pads at a second pitch outside a footprint of the bridge component.

### CROSS-REFERENCE TO RELATED APPLICATIONS

This is a continuation-in-part of U.S. Utility patent application Ser. No. 19/291,459, entitled “Fully Molded Bridge Interposer and Method of Making the Same,” which was filed on Aug. 5, 2025, which application is a continuation of U.S. Utility patent application Ser. No. 18/085,397, entitled “Fully Molded Bridge Interposer and Method of Making the Same,” which was filed on Dec. 20, 2022, which application is a continuation of U.S. Utility patent application Ser. No. 17/581,704, entitled “Fully Molded Bridge Interposer and Method of Making the Same,” which was filed on Jan. 21, 2022, which application claims the benefit, including the filing date, of U.S. Provisional Patent No. 63/141,945, entitled “Fully Molded Bridge Interposer and Method of Making the Same,” which was filed on Jan. 26, 2021, the disclosures of which are hereby incorporated herein by this reference.

### TECHNICAL FIELD

This disclosure relates to a fully molded bridge interposer and methods of making the same.

### BACKGROUND

Semiconductor devices are commonly found in modern electronic products. Semiconductor devices vary in the number and density of electrical components. Discrete semiconductor devices generally contain one type of electrical component, for example, light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, memories, analog to digital or digital to analog converters, power management and charged-coupled devices (CCDs), as well as microelectromechanical systems (MEMs) devices including digital micro-mirror devices (DMDs).

Semiconductor devices perform a wide range of functions such as signal processing, high-speed calculations, transmitting and receiving electromagnetic signals, controlling electronic devices, storing information, and creating visual projections for displays. Semiconductor devices are found in many fields of entertainment, communications, power conversion, networks, computers, and consumer products. Semiconductor devices are also found in military applications, aviation, automotive, industrial controllers, and office equipment.

Semiconductor devices exploit the electrical properties of semiconductor materials. The atomic structure of semiconductor material allows its electrical conductivity to be manipulated by the application of an electric field or base current or through the process of doping. Doping introduces impurities into the semiconductor material to manipulate and control the conductivity of the semiconductor device.

A semiconductor device contains active and passive electrical structures. Active structures, including bipolar, complementary metal oxide semiconductors, and field effect transistors, control the flow of electrical current. By varying levels of doping and application of an electric field or base current, the transistor either promotes or restricts the flow of electrical current. Passive structures, including resistors, capacitors, and inductors, create a relationship between voltage and current necessary to perform a variety of electrical functions. The passive and active structures are electrically connected to form circuits, which enable the semiconductor device to perform high-speed calculations and other useful functions.

Semiconductor devices are generally manufactured using two complex manufacturing processes, that is, front-end manufacturing, and back-end manufacturing, each involving potentially hundreds of steps. Front-end manufacturing involves the formation of a plurality of semiconductor die on the surface of a semiconductor wafer. Each semiconductor die is typically identical and contains circuits formed by electrically connecting active and passive components. Back-end manufacturing involves singulating individual semiconductor die from the finished wafer and packaging the die to provide structural support and environmental isolation. More recently, back-end manufacturing has been expanded to included emerging technology that allows multiple semiconductor die to be interconnected within a single package or device unit, thereby expanding the conventional definition of back-end technology. The term “semiconductor die” as used herein refers to both the singular and plural form of the words, and accordingly can refer to both a single semiconductor device and multiple semiconductor devices.

One goal of semiconductor manufacturing is to produce smaller semiconductor devices. Smaller devices typically consume less power, have higher performance, can be produced more efficiently, have a smaller form factor, and may be less cumbersome when integrated within wearable electronics, portable handheld communication devices, such as phones, and in other applications. In other words, smaller semiconductor devices may have a smaller footprint, a reduced height, or both, which is desirable for smaller end products. A smaller semiconductor die size can be achieved by improvements in the front-end process resulting in semiconductor die with smaller, higher density active and passive components. Back-end processes may result in semiconductor device packages with a smaller footprint by improvements in electrical interconnection and packaging materials.

### SUMMARY

In some aspects, the disclosure concerns a semiconductor assembly, including: a bridge component including conductive studs disposed over a frontside, a backside opposite the conductive studs, and no vias formed through the bridge component, wherein the bridge component includes one or more interconnect layers disposed over the frontside and an outermost interconnect layer is coupled to the conductive studs; conductive vertical interconnects formed as copper posts disposed in a periphery of the semiconductor assembly; an encapsulant disposed on five sides of the bridge component, on sides of the conductive studs, and on sides of the copper posts that leave ends of the conductive studs and opposing first and second ends of the copper posts coplanar with top and bottom surfaces of the encapsulant, wherein the encapsulant is not disposed over the backside of the bridge component; a frontside build-up interconnect structure over the conductive studs of the bridge component and coupled to first ends of the copper posts opposite the second ends of the copper posts, the frontside build-up interconnect structure including first pads at a first pitch within a footprint of the bridge component of less than or equal to 80 μm and second pads at a second pitch outside a footprint of the bridge component of greater than or equal to the first pitch.

In some aspects, the disclosure concerns a semiconductor assembly, wherein the bridge component includes one or more of an active device and a passive device.

In some aspects, the disclosure concerns a semiconductor assembly, wherein the bridge component further includes one or more planarization layers disposed between two or more interconnect layers.

In some aspects, the disclosure concerns a semiconductor assembly, wherein the bridge component includes up to and including 8 build-up interconnect structures and one or more planarization layers disposed between the build-up interconnect structures.

In some aspects, the disclosure concerns a semiconductor assembly, further including a misalignment of the bridge component with respect to an assembly edge is greater than a misalignment of an under bump metallization (UBM) with respect to the assembly edge.

In some aspects, the disclosure concerns a semiconductor assembly, further including a backside build-up interconnect structure formed over a backside of the bridge component and coupled to first ends of the copper posts.

In some aspects, the disclosure concerns a semiconductor assembly, wherein: the semiconductor assembly further includes a total thickness less than or equal to 150 μm; and the semiconductor assembly is disposed over, and is coupled to, a package substrate, a printed circuit board (PCB), a multilayer ceramic capacitors (MLCC), or a passive device.

In some aspects, the disclosure concerns a semiconductor assembly, including: a bridge component formed without vias extending through the bridge component, and including conductive studs, wherein the bridge component includes one or more interconnect layers disposed over a frontside of the bridge component and an outermost interconnect layer is coupled to the conductive studs; conductive vertical interconnects disposed in a periphery of the semiconductor assembly; an encapsulant disposed on five sides of the bridge component, on sides of the conductive studs, and on sides of the conductive vertical interconnects that leave ends of the conductive studs and opposing first and second ends of the conductive vertical interconnects coplanar with top and bottom surfaces of the encapsulant; a frontside build-up interconnect structure over the conductive studs of the bridge component and coupled to first ends of the conductive vertical interconnects opposite the second ends of the conductive vertical interconnects, the frontside build-up interconnect structure including first pads at a first pitch within a footprint of the bridge component and second pads at a second pitch outside a footprint of the bridge component.

In some aspects, the disclosure concerns a semiconductor assembly, wherein the bridge component includes one or more of an active device and a passive device.

In some aspects, the disclosure concerns a semiconductor assembly, wherein the bridge component further includes one or more planarization layers disposed between two or more interconnect layers.

In some aspects, the disclosure concerns a semiconductor assembly, wherein the bridge component includes up to and including eight interconnect layers and one or more planarization layers disposed between the interconnect layers.

In some aspects, the disclosure concerns a semiconductor assembly, further including a misalignment of the bridge component with respect to an assembly edge is greater than a misalignment of an under bump metallization (UBM) with respect to the assembly edge.

In some aspects, the disclosure concerns a semiconductor assembly, further including: a first component including a system on chip (SOC) integrated circuit, memory controller or high bandwidth memory (HBM) controller, voltage regulator, a serializer/deserializer (SERDES), or active semiconductor die, the first component including high density interconnects coupled with the first pads, and low density interconnects coupled with the second pads; and a second component including a SOC integrated circuit, memory controller or HBM controller, voltage regulator, a SERDES, or active semiconductor die, the second component including, high density interconnects coupled with the first pads, and low density interconnects coupled with the second pads.

In some aspects, the disclosure concerns a semiconductor assembly, wherein the first pitch within a footprint of the bridge component is less than or equal to 80 μm and the second pitch outside a footprint of the bridge component is greater than or equal to the first pitch.

In some aspects, the disclosure concerns a semiconductor assembly, wherein: the semiconductor assembly further includes a total thickness less than or equal to 150 μm; and the semiconductor assembly is disposed over, and is coupled to, a package substrate, a printed circuit board (PCB), a multilayer ceramic capacitors (MLCC), or a passive device.

In some aspects, the disclosure concerns a method of making a semiconductor assembly, including: providing a temporary carrier; disposing conductive vertical interconnects in a periphery of a bridge component site; disposing a bridge component over the carrier and within the bridge component site, wherein the bridge component includes one or more interconnect layers disposed over a frontside and an outermost interconnect layer includes a plurality of conductive studs and the bridge component does not include vias through the bridge component; forming an encapsulant disposed on five sides of the bridge component, on sides of the conductive studs, and on sides of the conductive vertical interconnects that leave ends of the conductive studs and first ends of the conductive vertical interconnects exposed from the encapsulant, wherein the bridge component, conductive vertical interconnects, and encapsulant together form a molded bridge interposer; and forming a frontside build-up interconnect structure over the conductive studs of the bridge component and coupled to first ends of the conductive vertical interconnects opposite second ends of the conductive vertical interconnects, the frontside build-up interconnect structure including first pads at a first pitch within a footprint of the bridge component and second pads at a second pitch outside a footprint of the bridge component.

In some aspects, the disclosure concerns a method, further including: removing at least a portion of the carrier; and removing a portion of the encapsulant from over the conductive vertical interconnects and the conductive studs.

In some aspects, the disclosure concerns a method, wherein: a pitch of the conductive studs includes a pitch of greater than or equal to 80 μm; and the first pitch is less than or equal to the second pitch.

In some aspects, the disclosure concerns a method, further including forming a backside build-up interconnect structure formed over the temporary carrier before disposing the bridge component over the temporary carrier and over the backside build-up interconnect structure.

In some aspects, the disclosure concerns a method, wherein the bridge component includes an active device or a passive component.

In some aspects, the disclosure concerns a method, further including: coupling a first component including a system on chip (SOC) integrated circuit, memory controller or high bandwidth memory (HBM) controller, voltage regulator, a serializer/deserializer (SERDES), or active semiconductor die to the molded bridge interposer, the first component including interconnects coupled with a first portion of the first pads, and lower density interconnects coupled with a first portion of the second pads; and coupling a second component including a SOC integrated circuit, memory controller or HBM controller, voltage regulator, a SERDES, or active semiconductor die, the second component including interconnects coupled with a second portion of the first pads, and lower density interconnects coupled with a second portion of the second pads.

In some aspects, the disclosure concerns a method, further including a misalignment of the bridge component with respect to an assembly edge is greater than a misalignment of an under bump metallization (UBM) with respect to the assembly edge.

In some aspects, the disclosure concerns a method, further including forming the frontside build-up interconnect structure using unit specific patterning.

In some aspects, the disclosure concerns a method, wherein the bridge component further includes one or more planarization layers disposed between two or more interconnect layers.

In some aspects, the disclosure concerns a method, wherein the bridge component includes up to and including 8 interconnect layers and one or more planarization layers disposed between the interconnect layers.

The foregoing and other aspects, features, and advantages will be apparent to those of ordinary skill in the art from the specification, drawings, and the claims.

### BRIEF DESCRIPTION OF THE DRAWINGS

FIGS. 1A-1F illustrate existing semiconductor device designs including bridge interconnects.

FIGS. 2A-2C illustrate various structures comprising interconnect components or chiplets.

FIGS. 3A-3C illustrate bridge die comprising electrical interconnects being singulated from a native wafer.

FIGS. 3D-3F illustrate bridge die comprising additional layers and electrical interconnects disposed thereon.

FIGS. 4A-4H illustrate the formation of fully molded bridge interposer comprising the bridge die of FIGS. 3A-3C.

FIGS. 4I-4J illustrate further embodiments of a fully molded bridge interposer comprising the bridge die of FIGS. 3E-3F during a singulation process.

FIGS. 5A-5C illustrate various aspects of fully molded semiconductor structures comprising bridge die as part of a chiplet arrangement and mounted to a substrate.

FIGS. 5D-5E illustrate detail views of fully molded semiconductor structures or assemblies comprising the bridge die of FIGS. 3E-3F.

### DETAILED DESCRIPTION

This disclosure relates to fully molded semiconductor structures, devices, and packages, and more particularly to a fully molded bridge interposer. In some instances, the fully molded semiconductor structures may comprise routing for semiconductor devices comprising different pitches, such as high density and ultra-high density as described more fully herein.

The fully molded semiconductor structures or bridge interposer (and method for making and using the same) may comprise, or provide: (i) a simplified supply chain, (ii) when compared with a conventional interposer-removing a need for an expensive large silicon die with through silicon vias (TSVs), which can be very large die that are very expensive (at least in part) because of TSV technology, (iii) when compared with Intel's Embedded Multi-die Interconnect Bridge (EMIB) technology, providing the advantage of no need for specialized substate technology—a enabling or facilitating the use of a low-cost substrate, (iv) improved electrical performance from using plated Cu Post vs TSVs, (v) have available ultra-high density connections (of or about a 10 μm area array bond pad pitch) where bridge die are embedded, high density (of or about a 20 μm area array bond pad pitch) elsewhere, and (vi) high density connections between bridge die and other devices or packages.

At least some of the above advantages are available at least in part by using unit specific patterning (such as patterning, custom lithography) and build up interconnect structures such as a frontside build-up interconnect structure, which is also known under the trademark “Adaptive Patterning”) with respect the bridge die. Unit specific patterning: (i) allows to use high-speed chip attach for bridge die and AP will ensure alignment for high density interconnects between M-Series interposer and attached devices, (ii) aligns via to Cu Studs allowing largest contact vias with smallest studs (fine pitch), (iii) with respect to an interposer makes the molded bridge interposer including a frontside build-up interconnect structure much cheaper that a giant interposer die, (iv) with respect to EMIB, vias can be large compared to stud size and capture pad size, lithography defined vias (not laser drilled), (v) allows connections between devices inside the molded bridge interposer with unit specific patterning or routing to compensate for die shift (including bridge die shift) between embedded devices, which may include memory controllers, voltage regulators, SERDES, etc., and (vi) make embedding active devices more useful.

This disclosure, its aspects and implementations, are not limited to the specific package types, material types, or other system component examples, or methods disclosed herein. Many additional components, manufacturing and assembly procedures known in the art consistent with semiconductor manufacture and packaging are contemplated for use with particular implementations from this disclosure. Accordingly, for example, although particular implementations are disclosed, such implementations and implementing components may comprise any components, models, types, materials, versions, quantities, and/or the like as is known in the art for such systems and implementing components, consistent with the intended operation.

The word “exemplary,” “example” or various forms thereof are used herein to mean serving as an example, instance, or illustration. Any aspect or design described herein as “exemplary” or as an “example” is not necessarily to be construed as preferred or advantageous over other aspects or designs. Furthermore, examples are provided solely for purposes of clarity and understanding and are not meant to limit or restrict the disclosed subject matter or relevant portions of this disclosure in any manner. It is to be appreciated that a myriad of additional or alternate examples of varying scope could have been presented, but have been omitted for purposes of brevity.

Where the following examples, embodiments and implementations reference examples, it should be understood by those of ordinary skill in the art that other manufacturing devices and examples could be intermixed or substituted with those provided. In places where the description above refers to particular embodiments, it should be readily apparent that a number of modifications may be made without departing from the spirit thereof and that these embodiments and implementations may be applied to other technologies as well. Accordingly, the disclosed subject matter is intended to embrace all such alterations, modifications and variations that fall within the spirit and scope of the disclosure and the knowledge of one of ordinary skill in the art.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components are formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition can involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. In one embodiment, the portion of the photoresist pattern subjected to light is removed using a solvent, exposing portions of the underlying layer to be patterned. In another embodiment, the portion of the photoresist pattern not subjected to light, the negative photoresist, is removed using a solvent, exposing portions of the underlying layer to be patterned. The remainder of the photoresist is removed, such as by a stripping process, leaving behind a patterned layer. Alternatively, some types of materials are patterned by directly depositing the material into the areas or voids formed by a previous deposition/etch process using techniques such as electroless and electrolytic plating.

Patterning is the basic operation by which portions of the photoresist material are partially removed, so as to provide a pattern or electroplating template for the subsequent formation of structures, such as patterning redistribution layers (RDLs), under bump mentalization (UBM), copper posts, vertical interconnects, or other desirable structures. Portions of the semiconductor wafer can be removed using photolithography, photomasking, masking, oxide or metal removal, photography and stenciling, and microlithography. Photolithography includes forming a pattern in reticles or a photomask and transferring the pattern into the surface layers of the semiconductor wafer. Photolithography forms the horizontal dimensions of active and passive components on the surface of the semiconductor wafer in a two-step process. First, the pattern on the reticle, masks, or direct write imaging design file are transferred into a layer of photoresist. Photoresist is a light-sensitive material that undergoes changes in structure and properties when exposed to light. The process of changing the structure and properties of the photoresist occurs as either negative-acting photoresist or positive-acting photoresist. Second, the photoresist layer is transferred into the wafer surface. The transfer occurs when etching removes or electroplating adds the portion of the top layers of semiconductor wafer not covered by the photoresist. The chemistry of photoresists is such that the photoresist remains substantially intact and resists removal by chemical etching solutions while the portion of the top layers of the semiconductor wafer not covered by the photoresist is removed by etching or a layer is added by electroplating. The process of forming, exposing, and removing the photoresist, as well as the process of removing or adding a portion of the semiconductor wafer can be modified according to the particular resist used and the desired results. Negative or positive tones resist can be designed for solvent or base develop solutions.

In negative-acting photoresists, photoresist is exposed to light and is changed from a soluble condition to an insoluble condition in a process known as polymerization. In polymerization, unpolymerized material is exposed to a light or energy source and polymers form a cross-linked material that is etch-resistant. In most negative resists, the polymers are polyisopremes. Removing the soluble portions (i.e. the portions not exposed to light) with chemical solvents or base developers leaves a hole in the resist layer that corresponds to the opaque pattern on the reticle. A mask whose pattern exists in the opaque regions is called a clear-field mask.

In positive-acting photoresists, photoresist is exposed to light and is changed from relatively nonsoluble condition to much more soluble condition in a process known as photosolubilization. In photosolubilization, the relatively insoluble resist is exposed to the proper light energy and is converted to a more soluble state. The photosolubilized part of the resist can be removed by a solvent or a base in the development process. The basic positive photoresist polymer is the phenol-formaldehyde polymer, also called the phenol-formaldehyde novolak resin. Removing the soluble portions (i.e. the portions exposed to light) with chemical solvents or base developers leaves a hole in the resist layer that corresponds to the transparent pattern on the reticle. A mask whose pattern exists in the transparent regions is called a dark-field mask.

After removal of the top portion of the semiconductor wafer not covered by the photoresist, the remainder of the photoresist is removed, leaving behind a patterned layer. Alternatively, some types of materials are patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface can be beneficial or required to produce smaller and more densely packed active and passive components. Planarization can be used to remove material from the surface of the wafer and produce a uniformly flat surface. Planarization involves polishing the surface of the wafer with a polishing pad. An abrasive material and corrosive chemical are added to the surface of the wafer during polishing. Alternatively, mechanical abrasion without the use of corrosive chemicals is used for planarization. In some embodiments, purely mechanical abrasion is achieved by using a belt grinding machine, a standard wafer back grinder, or other similar machine. The combined mechanical action of the abrasive and corrosive action of the chemical removes any irregular topography, resulting in a uniformly flat surface.

Back-end manufacturing refers to cutting or singulating the finished wafer into the individual semiconductor die and then packaging the semiconductor die for structural support and environmental isolation. To singulate the semiconductor die, the wafer can be cut along non-functional regions of the wafer called saw streets or scribes. The wafer is singulated using a laser cutting tool, laser silicon lattice disruption process or saw blade. After singulation, the individual semiconductor die are mounted to a package substrate that includes pins or contact pads for interconnection with other system components. Contact pads formed over the semiconductor die are then connected to contact pads within the package. The electrical connections can be made with solder bumps, stud bumps, conductive paste, redistribution layers, or wirebonds. An encapsulant or other molding material is deposited over the package to provide physical support and electrical isolation. The finished package is then inserted into an electrical system and the functionality of the semiconductor device is made available to the other system components.

Back-end manufacturing as disclosed herein also does more than merely packaging an embedded device or the semiconductor die for structural support and environmental isolation. The packaging described herein further provides non-monolithic electrical interconnection of die for increased functionality & performance. Previously, nearly all advanced semiconductor die were monolithic systems on chips (SoCs) where all electrical interconnect occurred on the silicon wafer during front-end processing. Now, however, work that was traditionally the domain of front-end domain work may be handled or moved to the back-end manufacturing, allowing many semiconductor die (chiplets) to be connected with packaging technology to form a chiplet-based SoC (which is non monolithic) and provides a composite package with greater functionality. The chiplet approach may also decrease waste from defects, increase production efficiency, reliability, and performance.

The electrical system can be a stand-alone system that uses the semiconductor device to perform one or more electrical functions. Alternatively, the electrical system can be a subcomponent of a larger system. For example, the electrical system can be part of a portable hand-held electronic device, such as smart phone, a wearable electronic device, or other video or electronic communication device. Additionally, the electrical system may comprise a graphics component, network interface component, or other signal processing component that can be inserted into a computer or electronics device and may assist with such functions as mobile computing, artificial intelligence, and autonomous functions such as autonomous driving. The semiconductor package can include microprocessors, memories, application specific integrated circuits (ASIC), logic circuits, analog circuits, RF circuits, discrete devices, or other semiconductor die or electrical components. Miniaturization and weight reduction can be beneficial or essential for the products to be accepted by the market. The distance between semiconductor devices must be decreased to achieve higher density.

By combining one or more semiconductor devices, structures, or packages with fan-out technology, manufacturers can incorporate multiple components or elements into more highly compact and integrated electronic devices and systems. Because the semiconductor devices include sophisticated functionality, electronic devices can be manufactured less expensively and as part of a streamlined manufacturing process. The resulting devices are less likely to fail and less expensive to manufacture resulting in a lower cost for consumers.

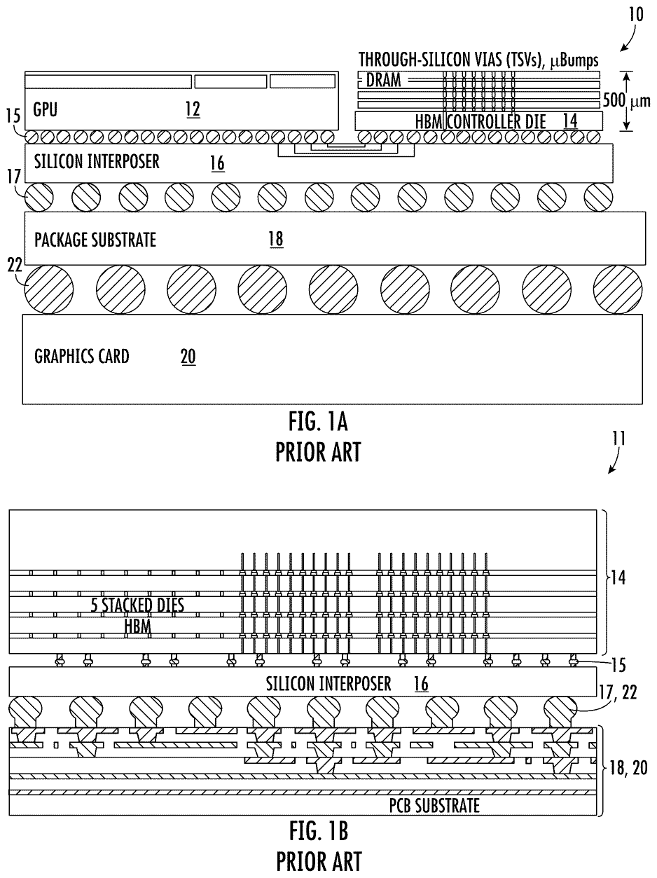

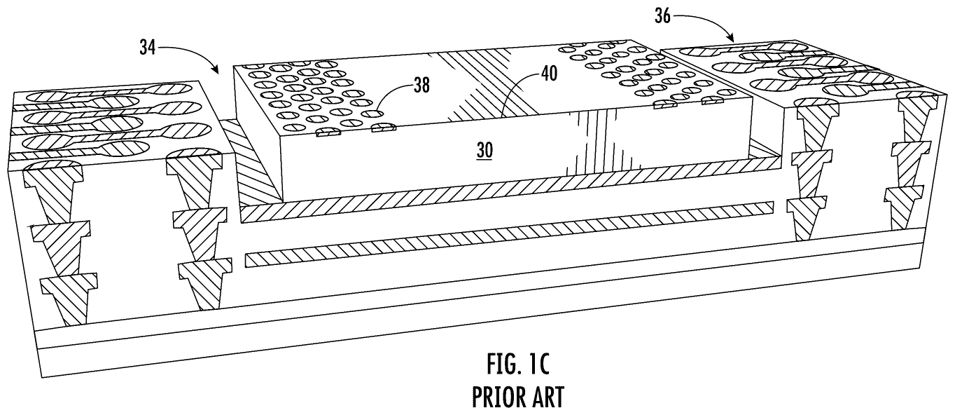

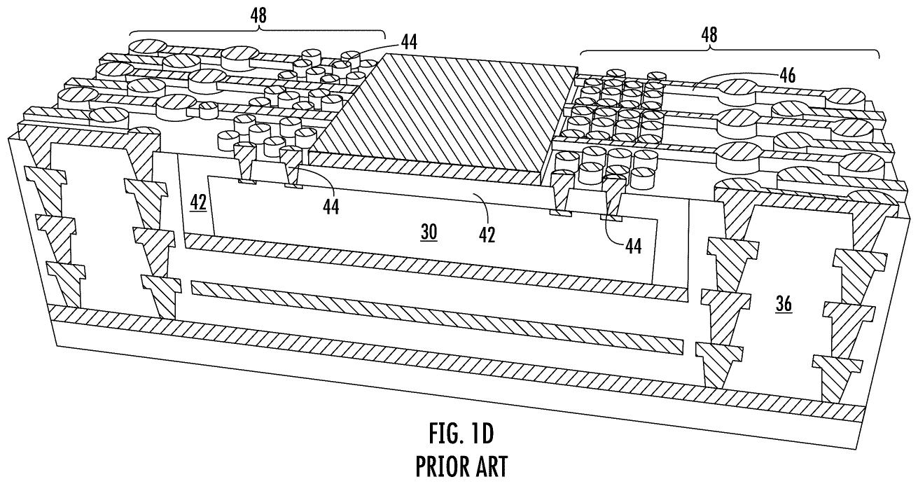

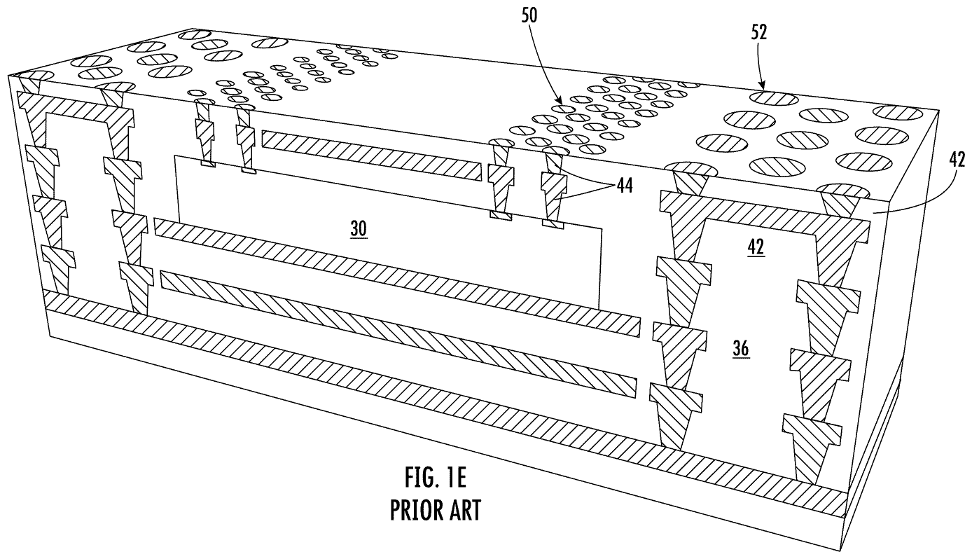

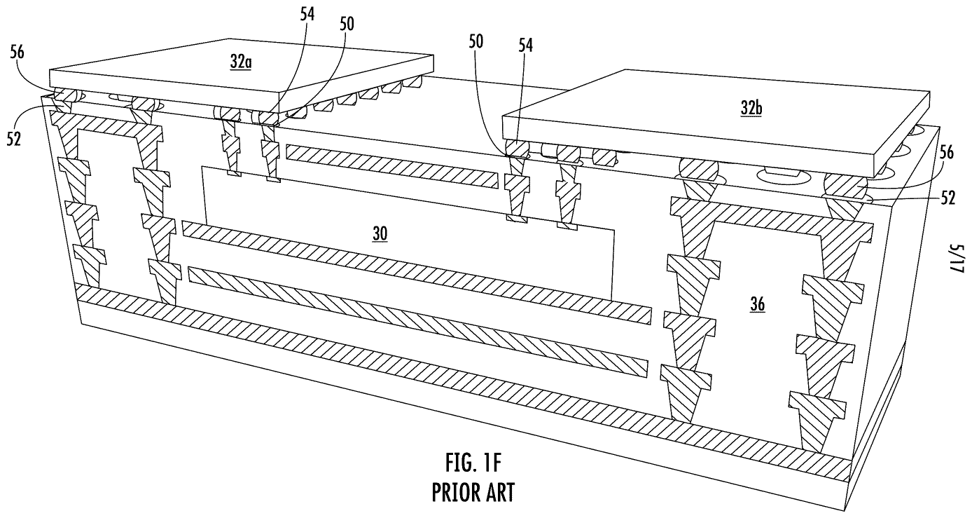

FIGS. 1A-1F show prior art relative to connecting multiple semiconductor die or semiconductor packages together, that may be used for high intensity or high demand computing, such as computing utilizing or dealing with graphics cards. FIG. 1A illustrates an existing packaging technology or structure 10 comprising a graphics processing unit (GPU 12) coupled to an HBM controller die 14 with bumps or microbumps 15 and through a silicon interposer 16 comprising silicon vias formed in and extending therethrough. The silicon interposer 16 may then be disposed over and coupled to a package substrate 18, with conductive or solder interconnects, bumps, or balls 17. The package substrate 18 may then be disposed over and coupled to a graphics card, a multilayer ceramic capacitors (MLCC), a PCB 20 or a passive device with conductive or solder interconnects, bumps, or balls 22. The graphics card 20 may comprise a multi-layer PCB, and the conductive bumps 20 may be used for: display connections, electrical current, as well as for peripheral component interconnect express (PCIe) interconnections or high-speed serial computer expansion bus connections.

FIG. 1B illustrates a representation of a cross-section structure 11 that could be seen by a scanning electron microscope (SEM) of an HBM 14 stacked on—and coupled to—a silicon interposer 16, which may further be coupled to a substrate, PCB, or graphics card 20. The structure 11 integrates HBM memories 14 (which may comprise DRAM die and Logic Die connected with via-middle TSV and micro-bumps) and the GPU 12 stacked onto the silicon interposer 16, wherein the silicon interposer 16 comprises via-middle through silicon vias (TSVs).

FIGS. 1C-1F illustrates an existing technology of Intel's Embedded Multi-die Interconnect Bridge (EMIB) 30, that was developed to provide a cost-effective approach to in-package high density interconnect of heterogeneous chips or semiconductor die 32.

FIG. 1C illustrates the EMIB 30 embedded in a cavity 34 of an organic substrate 36, the EMIB 30 comprises conductive pads or contact pads 38 coupled together with a conductive redistribution layer (RDL) 40. FIG. 1D illustrates resin 42 formed over the EMIB 30, and vias 44 formed in, or extending through, the resin 42 with the vias 44 further coupled with the EMIB 30. RDLs 46 may be formed over the resin 42 and over the EMIB 30 and coupled with the vias 44 for lateral connection that extend from the EMIB 30 and vias 44 to mounting sites 48 for heterogeneous chips 32. FIG. 1E illustrates additional vias 44 and layers of resin 42 formed over the EMIB 30 with contact pads for microbumps 50 formed over the EMIB 30 and contact pads for ordinary bumps 52 formed at semiconductor die mounting sites 48. FIG. 1F illustrates a first semiconductor die 32a on the left and a second semiconductor die 32b on the right, each mounted over respective semiconductor die sites 48 with microbumps 54 and ordinary bumps 56 and RDLs 40, 46 and vias 44 for routing of signals and interconnections for the semiconductor die 32a, 32b being routed through the organic substrate 36 and through the EMIB 30.

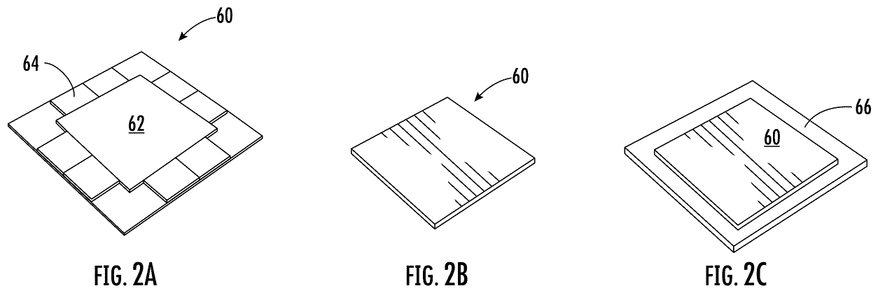

FIGS. 2A-2C illustrate a chiplet 60, including a grouping of multiple components 62, such as semiconductor die, semiconductor chips, semiconductor devices and other similar components interconnected and molded together. FIG. 2A illustrates a chiplet 60 (without encapsulant) comprising a central, larger, component 62, such as a semiconductor die, semiconductor chip, semiconductor device, and other similar components with multiple, additional, smaller components 64, such as multiple semiconductor die, semiconductor chips, semiconductor devices and other similar components disposed around and grouped together with component 62, such as in a fan-out arrangement. Chip type or function of the various components 62, 64 within the chiplet 60 may comprise a central processing unit (CPU), a modem, a graphics processing unit (GPU), chips, semiconductor die, or processors specialized for running artificial intelligence (AI) algorithms, chips, semiconductor die or processors specialized for input/output (I/O), Serializer/Deserializer (SERDES) devices, and various other memory devices such as chips or semiconductor die specialized for Cache or storing data, and chips specialized for high bandwidth memory (HBM) or high-speed computer memory. FIGS. 2B and 2C illustrate the same or similar chiplet 60 shown in FIG. 2A overmolded with encapsulant material, mold compound or a similar material, and in a fan-out arrangement. In FIG. 2C, the overmolded chiplet 60 is coupled to, or disposed over (or on) a substrate or package substrate 66, which may be further coupled to, or mounted on, a motherboard, a printed circuit board (PCB), a multilayer ceramic capacitors (MLCC), an interposer, a passive device, or another semiconductor device or package. The method and device described herein may be advantageously used for applications in which the device is mounted to a substrate and may also be used for instances in which it is not mounted to a substrate, like for applications within a handheld mobile electronic device, such as a smartphone or other wearable technology.

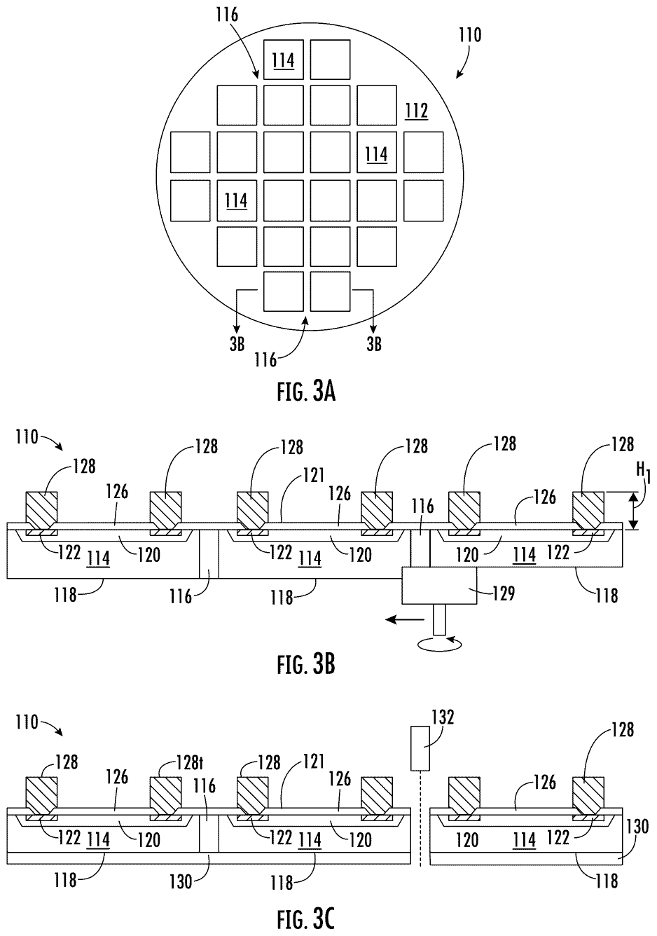

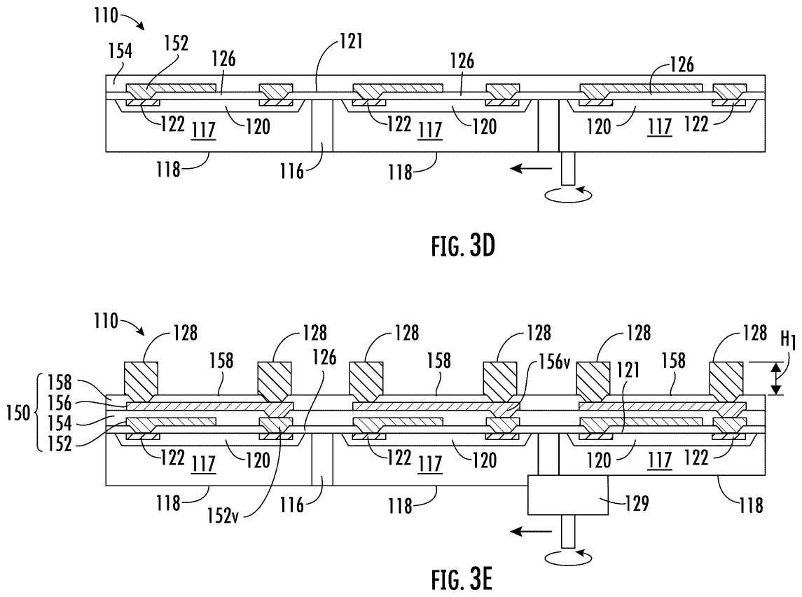

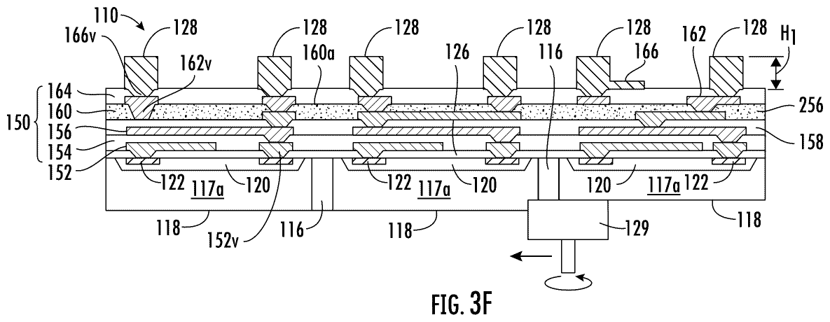

FIGS. 3A-3C show various views of a wafer 110 and the formation and separation of individual components 114 therefrom. FIG. 3A illustrates a plan view of the wafer 110, such as a semiconductor wafer, native wafer and other, similar structures, comprising a base substrate material 112, such as, without limitation, silicon, germanium, gallium arsenide, indium phosphide, silicon carbide and similar materials, for structural support. A plurality of components 114, including semiconductor die, embedded devices, bridge die, silicon components with or without TSVs, and other similar components, can be formed on wafer 110 separated by a non-active, inter-die wafer area or saw street 116 as described above. The saw street 116 can provide cutting areas to singulate the wafer 110 into the individual components 114.

Each component 114 may comprise a backside or back surface 118 and a front surface 121. In some embodiments, components 114 may comprise an active surface 120 opposite the backside 118. Each component 14 may comprise one or more active devices, passive devices, or both active devices and passive devices. In some instances, both the active layer 120 and the backside or back surface 18 of the component 114 may be active. In some instances, the component 114 may be formed without active and passive devices, and be used for transmission or routing, such as by comprising TSVs for vertical interconnect. The active surface 120 of the component 114 may contain one or more analog or digital circuits, diodes, or transistors implemented as active devices, passive devices, conductive layers, and dielectric layers formed within or on the component 114 and electrically interconnected according to the electrical design and function of the semiconductor die 114, and may comprise a processor or logic device. For example, the component 114 may comprise circuits that may include one or more transistors, a FET, a JFET, a MOSFET, a BJT, an IGBT, a SIT, diodes, a Schottky transistor diode, and other circuit elements formed within active surface 120 of the chip substrate and close to the front surface 121 to implement analog circuits or digital circuits, such as one or more of a DSP, ASIC, memory, or other circuits. Circuits may include RF circuits, LED, LCOS, CIS, transistor, optoelectronic, MEMS and the like. The component 114 may also contain IPDs such as inductors, capacitors, and resistors, RF signal processing, digital or analog power line control, clocking, and other functions. The component 114 may be formed on a native wafer in a wafer level process as one of many packages being formed simultaneously on a carrier. In other instances, the component 114 may be formed as part of a reconstituted wafer, and may comprise multiple components molded together. The component 114 may also be another suitable embedded device, which is subsequently formed within a fully-molded bridge interposer 300, and surrounded (partially or entirely) by encapsulant 256. The component 114 within the fully molded bridge interposer 300 may be an active die or a bridge die or chip formed without an active surface 120 with only electrical routing, and with copper studs of the bridge die 114 electrically connected or coupled with wiring, routing, or RDLs. The component 114 may also be only a dummy substrate with no electrical function, but rather act as structural element and may or may not include copper studs. In some embodiments, the component 114 may not include, and may be formed without, conductive studs.

FIG. 3B illustrates a cross sectional sideview of the wafer 110, as shown taken along the section line 3B-3B in FIG. 3A. FIG. 3B also illustrates an optional insulating layer 126, such as a dielectric layer, a passivation layer, and similar structures, conformally applied over the front surface 121, over active surface 120 and over conductive layer 122. Insulating layer 126 can include one or more layers that are applied using PVD, CVD, screen printing, spin coating, spray coating, sintering, thermal oxidation, or other suitable process. Insulating layer 126 can contain, without limitation, one or more layers of silicon dioxide (SiO₂), silicon nitride (Si₃N₄), silicon oxynitride (SiON), tantalum pentoxide (Ta₂O₅), aluminum oxide (Al₂O₃), polymer, polyimide, benzocyclobutene (BCB), polybenzoxazoles (PBO), or other material having similar insulating and structural properties. Alternatively, semiconductor die 114 are packaged without the use of any PBO layers, and insulating layer 126 can be formed of a different material or omitted entirely. In another embodiment, insulating layer 126 includes a passivation layer formed over the active surface 120 without being disposed over conductive layer 122. When insulating layer 126 is present and formed over conductive layer 122, openings are formed completely through insulating layer 126 to expose at least a portion of conductive layer 122 for subsequent mechanical and electrical interconnection. Alternatively, when insulating layer 126 is omitted, conductive layer 122 is exposed for subsequent electrical interconnection without the formation of openings.

FIG. 3B also illustrates conductive bumps 128, including conductive interconnects, bumps, studs, and electrical interconnect structures that can be formed of copper or other suitable conductive material, in shapes of columns, pillars, posts, thick RDLs, which are disposed over, and coupled or connected to, conductive layer 122. When formed as posts, the conductive bumps 128 will have a height greater than a thickness, whereas when the conductive bumps 128 are formed as a pillar, the conductive bumps 128 may have a tin cap. When the conductive bumps 128 are formed as a stud, the conductive bumps 128 may be wider than it is tall. Conductive bumps 128 can be formed directly on conductive layer 122 using patterning and metal deposition processes such as printing, PVD, CVD, sputtering, electrolytic plating, electroless plating, metal evaporation, metal sputtering, or other suitable metal deposition process. Conductive bumps 128 can be one or more layers of Al, Cu, Sn, Ni, Au, Ag, palladium (Pd), or other suitable electrically conductive material and can include one or more layers. In some instances, one or more UBM layers of Al, Cu, Sn, Ni, Au, Ag, Pd, or other suitable electrically conductive material can optionally be disposed between conductive layer 122 and conductive bumps 128. In some embodiments, conductive bumps 128 can be formed by depositing a photoresist layer over the component 114 and conductive layer 122 while the components 114 are part of the wafer 110. A portion of the photoresist layer can be exposed and removed by an etching development process, and the conductive bumps 128 can be formed as copper pillars in the removed portion of the photoresist and over conductive layer 122 using a selective plating process. The photoresist layer can be removed leaving conductive bumps 128 that provide for subsequent mechanical and electrical interconnection and a standoff with respect to front surface 121. Conductive bumps 128 can include a height H1 in a range of 5-100 micrometers (μm) or a height in a range of 20-50 μm, or a height of about 25 μm.

FIG. 3B also illustrates the wafer 110 can undergo an optional grinding operation with a grinder 129 to planarize the surface and reduce a thickness of the wafer 110. A chemical etch can also be used to remove and planarize a portion of the wafer 110.

FIG. 3C illustrates attaching a die attach film (DAF) 130 to the wafer 110 that can be disposed over, and in direct contact with, the backsides 118 of the components 114. The DAF 130 can comprise epoxy, thermal epoxy, epoxy resin, B-stage epoxy laminating film, ultraviolet (UV) B-stage film adhesive layer, UV B-stage film adhesive layer including acrylic polymer, thermo-setting adhesive film layer, a suitable wafer backside coating, epoxy resin with organic filler, silica filler, or polymer filler, acrylate based adhesive, epoxy-acrylate adhesive, a polyimide (PI) based adhesive, or other adhesive material.

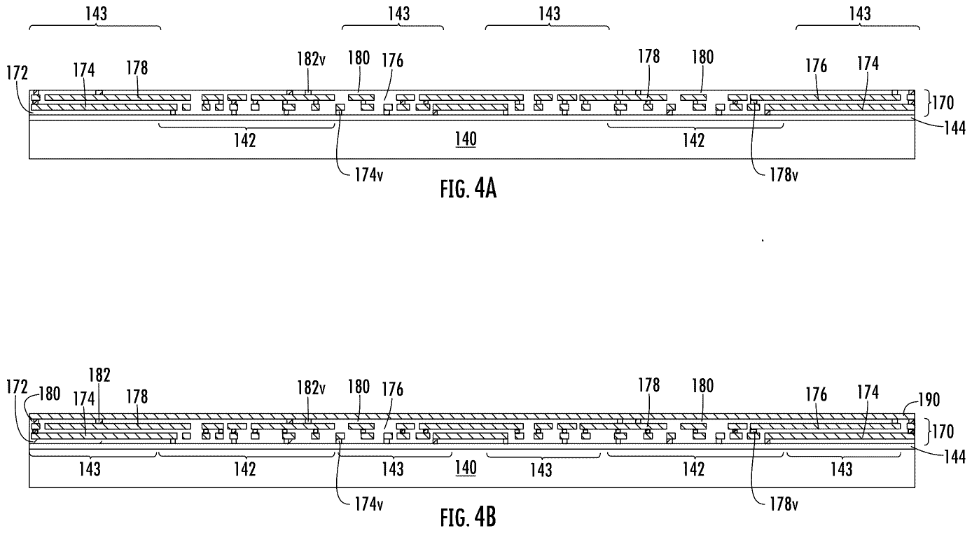

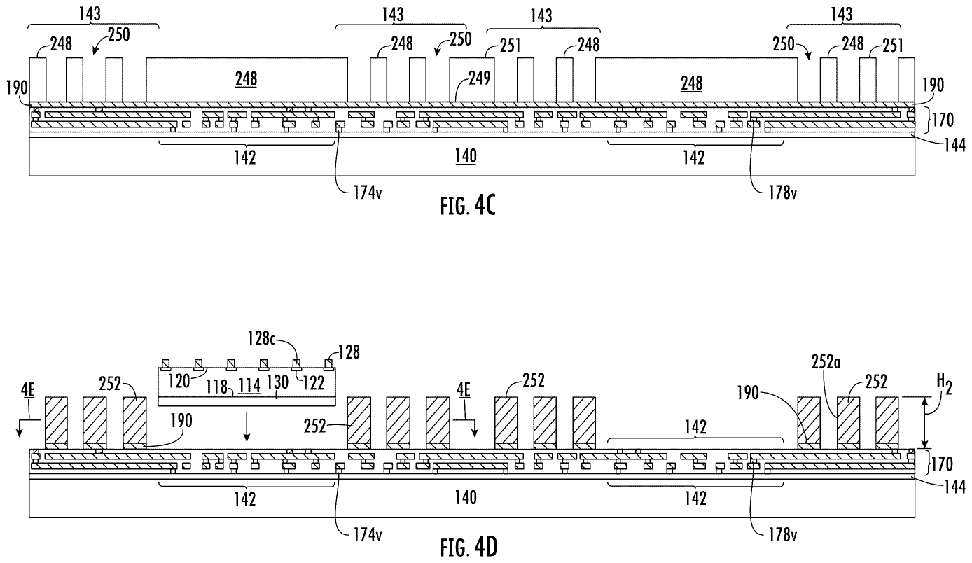

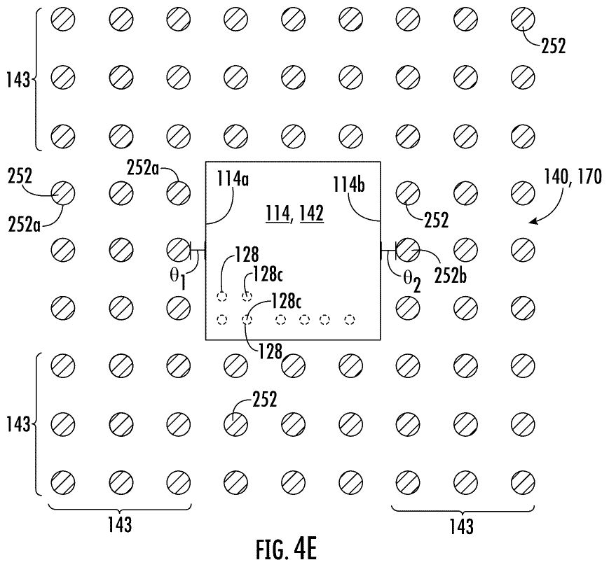

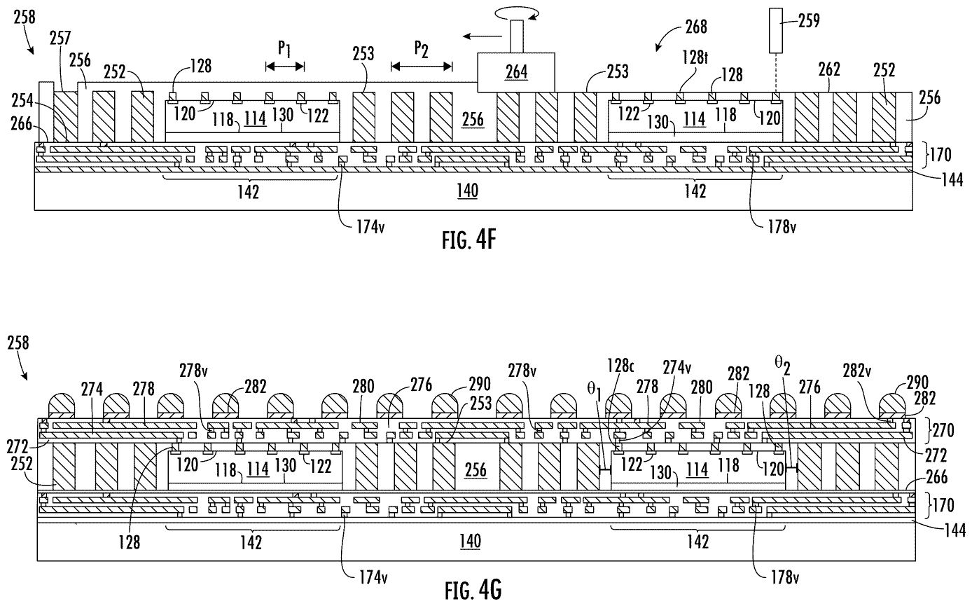

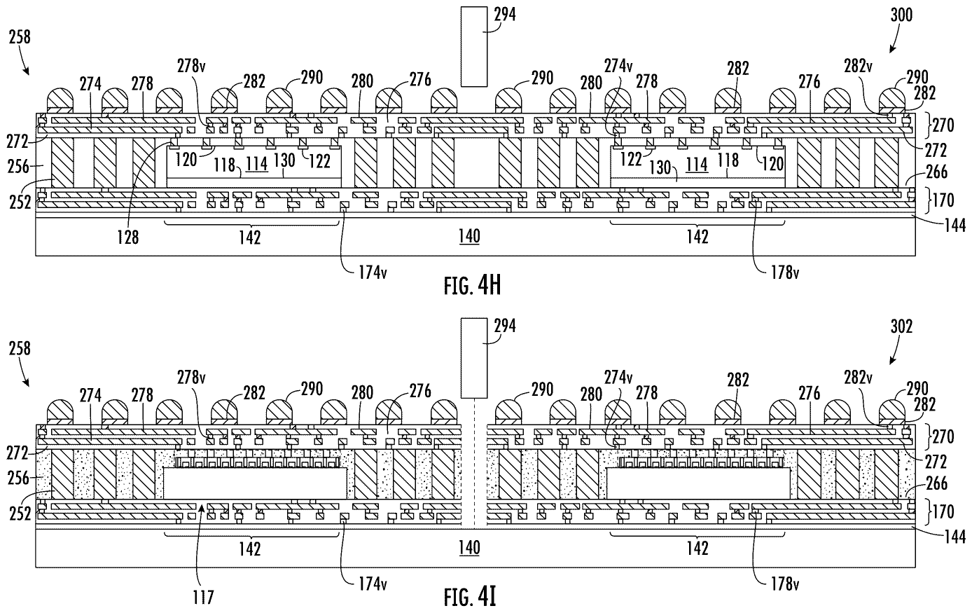

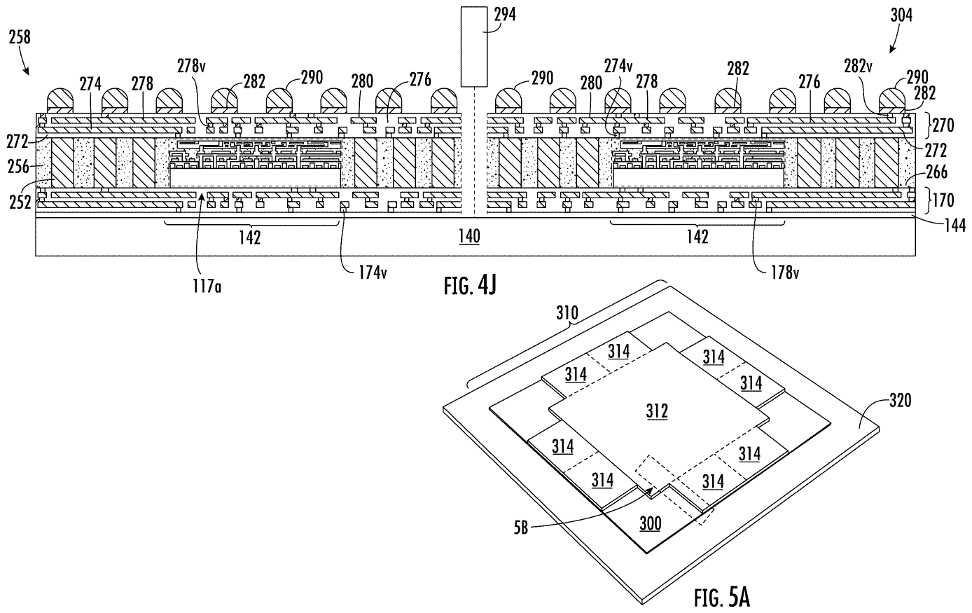

FIG. 3C also illustrates wafer 110 can be singulated through gaps or saw streets 116 using laser grooving, a saw blade or laser cutting tool 132, or both to singulate the wafer 110 into individual components 114 with conductive bumps 128, comprising tops 128t of conductive bumps 128. The components 114 can then be used as part of a subsequently formed component package as discussed in greater detail below with respect to FIGS. 4A-4J.

Similar to FIGS. 3A-3C, FIGS. 3D-3F show embodiments of a wafer 110 and the formation of components 117, such as semiconductor die, embedded devices, bridge die, silicon bridge components with or without TSVs, and other similar components. The wafer 110 may be separated into individual components 117, 117a as shown and described with respect to FIG. 3C. The wafer 110 and individual components 117, 117a of FIGS. 3D-3F may comprise additional layers disposed thereon in subsequent processes performed after, or as part of, wafer fabrication. FIG. 3D depicts where wafer 110 comprises a first conductive layer 152, such as an interconnect layer, an RDL layer, an outermost interconnect layer, and similar structures, formed over insulating layer 126 and coupled or connected to, conductive layer 122 by vias 152v disposed in openings formed in insulating layer 126. First conductive layer 152 may be formed in a similar, or same, manner as shown and described for first electrically conductive layer 174, and formed of similar, or the same, electrically conductive materials and layers. FIG. 3D further depicts where a first insulating layer 154, such as a passivation layer, a dielectric layer, and similar layers as shown and described for first insulating layer 172, may be disposed over frontside 121 of the component 117 and over first conductive layer 152.

FIG. 3E, continuing from FIG. 3D, shows where a second conductive layer 156, such as an interconnect layer, an RDL layer, an outermost conductive layer, an outermost RDL layer and similar structures, may be formed in a similar, or same, manner as shown and described for first conductive layer 152 and may be formed of similar, or the same, electrically conductive materials and layers. Second conductive layer 156 may be disposed over first insulating layer 154 and may comprise vias 156v disposed in openings formed in first insulating layer 154, as shown and described for conductive layers 174, 178, and vias 182v of FIG. 4A. A second insulating layer 158, such as a passivation layer, a dielectric layer, and similar layers which may be similar to or the same as first insulating layer 154, may be disposed over the second conductive layer 156 and first insulating layer 154 to form build-up interconnect 150 of component 117. In some embodiments, up to and including eight layers, comprising combinations of conductive layers and insulating layers may be formed. In some embodiments, the second conductive layer 156 may comprise an outermost RDL and may have conductive bumps 128 coupled thereto, the conductive bumps 128 may be the same as, or similar to as shown and described previously for FIGS. 3B and 3C for interconnection to additional components, build-up structures, or peripheral devices. In additional embodiments, the second conductive layer 156 may comprise interconnect pads or thick RDLs, formed over the second conductive layer 156 for interconnection to additional components, build-up structures, or peripheral devices. A person of ordinary skill in the art (a “POSA”) would understand that additional conductive layers and dielectric layers may be formed, although not depicted.

FIG. 3F shows an embodiment of the build-up interconnect structure 150 of FIG. 3E, further comprising a planarization layer 160 disposed between second insulating layer 158 and third insulating layer 164, where the third insulating layer 164 may be the same as, or similar to, second insulating layer 158 and may comprise an outermost insulating layer. The planarization layer 160 may be formed of an encapsulant or mold compound similar to, or the same as, encapsulant or mold compound 256 as earlier described. Openings may be formed in planarization layer 160, and vias 162v as part of third conductive layer 162, may be disposed therein for connection to second conductive layer 156 and fourth conductive layer 166, similar to as shown and described for conductive layers 174, 178, and vias 182v of FIG. 4A. The planarization layer 160 can undergo an optional grinding or planarization operation with grinder 264 (similar to as shown and described for the molded panel of FIG. 4F) to form a planarized top surface 160a of planarization layer 160 and reduce surface roughness for deposition of additional fine pitch RDL and dielectric layers.

In some embodiments, the planarized top surface 160a comprises a roughness less than 500 nanometers (nm) over a characteristic measurement distance. The characteristic measurement distance is defined by the ISO 4288 standard, an entirety of which is hereby incorporated by reference. The characteristic measurement distance may also be a distance great enough to characterize the roughness, such as to a generally accepted level of certainty, and in some instances could be a distance of three times the distance of the roughness. While conventional encapsulant grinding might be done with less flatness, greater accuracy and precision can be obtained by using integrated sensors such as laser, acoustic, or other non-contact methods to control the grinding, resulting in better flatness and reduced roughness. The planarization layer 160 may comprise a molded direct contact interconnect structure (also known under the trademark “MDx”™). Molded direct contact interconnect build-up structures (and a methods for making and using the same) are discussed in U.S. Pat. Nos. 11,973,051, 12,062,550, and 12,170,261, the entire disclosures of which are incorporated herein by this reference. Use of one or more planarization layers 160, interleaved between dielectric layers 154, 158, 164 and additional, and conductive layers 152, 156, 162 and additional, as part of build-up interconnect structure 150, provides the benefit of reducing deformations, including dips, waves, or undulations present in conventional, known build-up interconnect structures, which follow contours from lower layers, including dielectric layers and conductive layers which make manufacturing more difficult and often increase manufacturing cost. A POSA would understand that additional planarization layers 160 may be interleaved with dielectric layers 154, 158, 162 and conductive layers 152, 156, such as eight conductive layers each separated by dielectric layers, with one or more planarization layers disposed therebetween. Similar to as shown in FIG. 3E, a fourth conductive layer 166, such as an interconnect layer, an RDL layer, an outermost conductive layer, an outermost RDL layer and similar structures, may comprise fourth level conductive vias 166v disposed in openings formed in third insulating layer 164, and may be formed over the planarization layers 160 and coupled to third electrically conductive layer 162. In some embodiments, the fourth conductive layer 166 may comprise an outermost RDL and may have conductive bumps 128 coupled thereto, the conductive bumps 128 may be the same as, or similar to as shown and described previously for FIGS. 3B, 3C and 3D for interconnection to additional components, build-up structures, or peripheral devices.

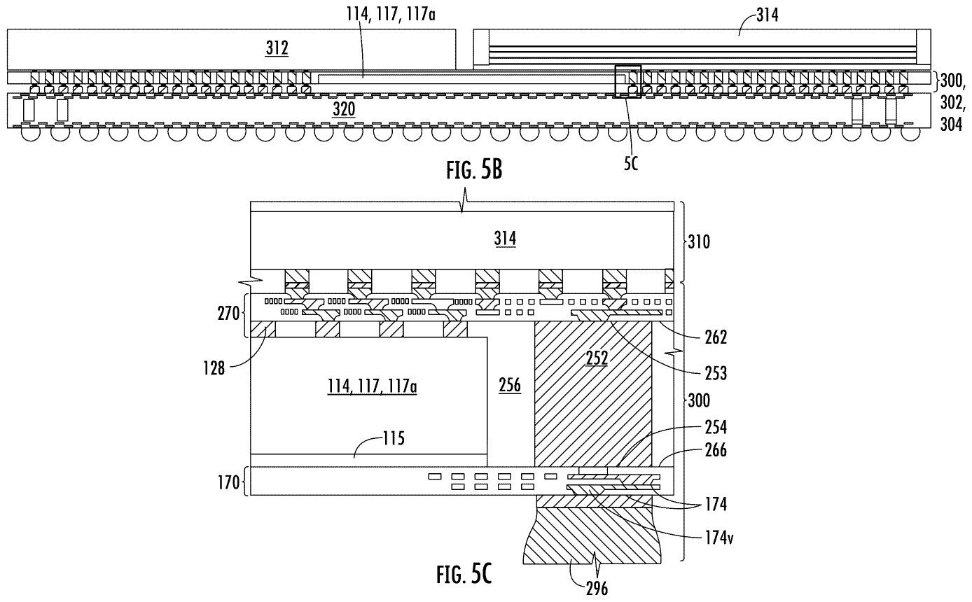

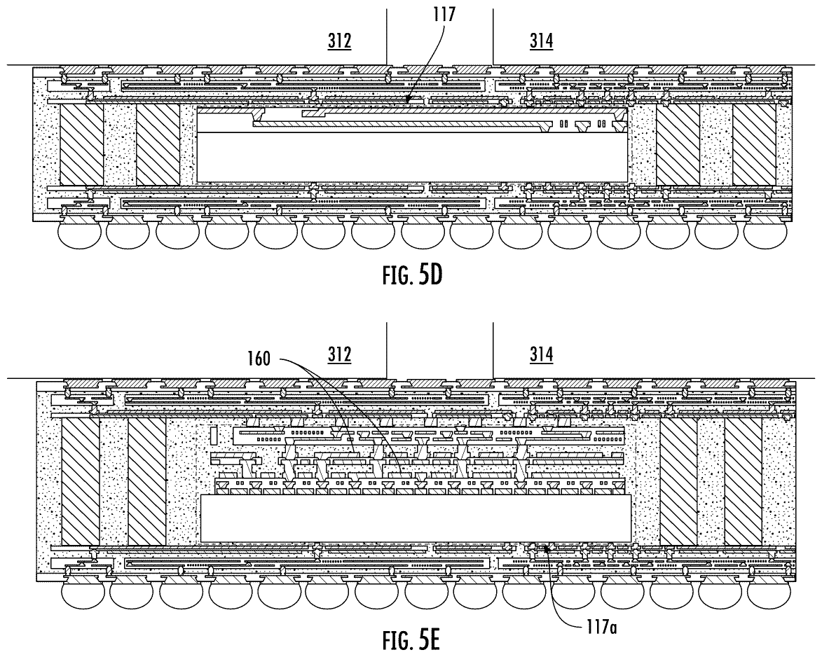

FIGS. 4A-5C, illustrate a structure, method, process flow for forming the fully molded bridge interposer 300, such as a component interposer, component device, semiconductor device, semiconductor assembly, and other, similar structures, where the interposer 300 may comprise one or more components and peripheral posts. FIG. 4A illustrates providing a carrier 140, such as a temporary carrier, substrate or similar support structure, on which subsequent processing of the fully-molded bridge interposer 300 can occur, as described in greater detail herein. Carrier 140 may be a temporary or sacrificial carrier or substrate, and may also be a reusable carrier or substrate. The carrier 140 may be of any desirable or suitable size, including a circular shape comprising a range of diameters, for example from 300 mm to 600 mm and greater.

The carrier 140 can comprise one or more base materials formed in one or more layers, which may comprise base materials such as metal, silicon, polymer, polymer composite, ceramic, perforated ceramic, glass, glass epoxy, stainless steel, mold compound, mold compound with filler, or other suitable low-cost, rigid material or bulk semiconductor material for structural support. When a UV release is used with the carrier 140, the carrier 140 may comprise one or more transparent or translucent materials, such as glass. When a thermal release is used with a carrier 140, the carrier 140 may comprise opaque materials. The carrier 140 can be circular, square, rectangular, or other suitable or desirable shape and can include any desirable size, such as a size equal to, similar to, or slightly larger or smaller than a reconstituted wafer or panel that is subsequently formed on or over the carrier 140. In some instances, a diameter, length, or width of the temporary carrier 140 can be equal to, or about, 200 millimeters (mm), 300 mm, 600 mm or more.

The carrier 140 can comprise a plurality of component mounting sites or component attach areas 142 spaced or disposed across a surface of the carrier 140, according to a design and configuration of the final fully-molded bridge interposer 300, to provide a peripheral area or space 143. The peripheral area 143 can partially or completely surround the die attach areas 142 to provide space for subsequent vertical, through package interconnections, and an area for fan-out routing or build-up interconnect structures. For example, the peripheral area 143 can surround, or be offset from, one side of the component 114, or more than one side of the component 114, such as 2, 3, 4, or more sides of the component 114.

When a temporary carrier 140 is used, an optional release layer, interface layer or double-sided tape 144 can be formed over carrier 140 as a temporary adhesive bonding film or etch-stop layer. The release layer 144 may be a film or laminate, and may also be applied by spin coating or other suitable process. The temporary carrier can be subsequently removed by strip etching, chemical etching, mechanical peel-off, CMP, plasma etching, thermal, light releasing process, mechanical grinding, thermal bake, laser scanning, UV light, or wet stripping.

FIG. 4A further illustrates forming a build-up interconnect structure 170 over the carrier 140 to electrically connect, and provide routing between, conductive interconnects 252, the conductive bumps 128, and in some embodiments to provide routing between other devices mounted on, or coupled with, the fully-molded bridge interposer 300. While the build-up interconnect structure 170 is shown comprising three conductive layers and three insulating layers, a POSA will appreciate that fewer layers or more layers can be used depending on the configuration and design of the fully-molded bridge interposer 300. The build-up interconnect structure 170 can comprise a first insulating layer 172, such as a passivation layer, a dielectric layer, and layers made of similar materials, formed or disposed over the carrier 140. The first insulating layer 172 can comprise one or more layers of SiO₂, Si₃N₄, SiON, Ta₂O₅, Al₂O₃, polymer, polyimide, BCB, PBO, or other material having similar insulating and structural properties. The insulating layer 172 can be formed using PVD, CVD, printing, spin coating, spray coating, sintering or thermal oxidation. Openings which may be filled by first level conductive vias 174v can be formed through the insulating layer 172 for subsequent interconnection with bumps 296, such as lower bumps, balls, a ball grid array (BGA), solder bumps, or interconnect structures.

A first conductive layer 174 can be formed over the carrier 140 and over the first insulating layer 172 as a first RDL layer to extend through openings in the first insulating layer 172, to electrically connect with first level conductive vias 174v, and to electrically connect with the conductive interconnects 252, and bumps 296. Conductive interconnects 252 may comprise structures such as conductive posts, copper posts, conductive pillars and other, similar structures. Conductive layer 174 can be one or more layers of Al, Cu, Sn, Ni, Au, Ag, or other suitable electrically conductive material formed using a patterning and metal deposition process such as sputtering, electrolytic plating, and electroless plating, or other suitable process. First level conductive vias 174v may comprise similar materials formed in a similar manner as that of conductive layer 174.

In some instances, the conductive layer 174 within the build-up interconnect structure 170 can be formed as UBMs which are the same as, or similar to, UBMs as shown and subsequently described for third conductive layer 282, that are formed over the first insulating layer 172 to electrically connect with the other conductive layers and conductive vias within the build-up interconnect structure 170, as well as electrically connect to the component 114, the conductive bumps 128, the conductive interconnects 252, and bumps 296.

A second insulating layer 176, which can be similar or identical to the first insulating layer 172, can be disposed or formed over the carrier 140, the first conductive layer 174, and the first insulating layer 172. An opening can be formed through the second insulating layer 176, and second level conductive vias 178v formed therein to electrically connect with the first conductive layer 174.

A second conductive layer 178, when desirable and when present, may be similar or identical to the first conductive layer 174, and can be formed as a second RDL layer such as over substrate 140, over the first insulating layer 172, over the first conductive layer 174, over the second level conductive vias 178v, and within an opening of the second insulating layer 178, to electrically connect with the first conductive layer 174, the first level and second level conductive vias 174v, 178v, conductive interconnects 252, and the component 114.

A third insulating or passivation layer 180, when desirable and when present, may be similar or identical to the first insulating layer 172, can be disposed or formed over the second conductive layer 178 and the second insulating layer 176. An opening can also be formed in or through the third insulating layer 180 and third level conductive vias 182v formed therein to electrically connect with the second conductive layer 178.

A third conductive layer 182, when desirable and when present, may be similar or identical to the second conductive layer 178, can be formed as a third RDL layer—and comprising vias or third level conductive vias 182v disposed over and (or) through the third insulating layer 180, and further disposed over the second insulating layer 176, over the second conductive layer 178, over the second level conductive via 178v or within an opening of the second insulating layer 176, to electrically connect with the second conductive layer 178, conductive interconnects 252, and the component 114.

FIG. 4B further illustrates forming a seed layer 190 over the build-up interconnect structure 170. The seed layer 190 can be one or more layers of Al, Cu, Sn, Ni, Au, Ag, Titanium (Ti), Tungsten (W) or other suitable electrically conductive material. In some instances, the seed layer 190 will be, or may include, Ti/Cu, Ti/W/Cu, W/Cu or a coupling agent/Cu. The formation, placement, or deposition of the seed layer 190 can be with PVD, CVD, electrolytic plating, electroless plating, or other suitable process. The seed layer 190 can be deposited by sputtering, electroless plating, or by depositing laminated foil, such as Cu foil, combined with electroless plating.

FIG. 4C illustrates forming or depositing a resist layer or photosensitive layer 248 over and directly contacting seed layer 190, over build-up interconnect structure 170, and over the temporary carrier 140. After formation of the resist layer 248 over the temporary carrier, the resist layer 248 can then be exposed and developed to form openings 250 in the resist layer 248. In some instances, more than one photoresist layer 248 may be used. Openings 250 may be formed in the photoresist 248, and can be positioned over, or within a footprint of, the peripheral area 143 of the carrier 140. The openings 250 can extend completely through the resist layer 248, such as from a first surface or bottom surface 249 of the resist layer 248 to second surface or top surface 251 of the resist layer 248 opposite the first surface 249. An after development inspection (ADI) of the developed resist layer 248 and the openings 250 can be performed to detect the condition or quality of the openings 250. After the ADI of resist layer 248 and openings 250, a descum operation can be performed on the developed resist layer 248.

FIG. 4D shows the formation of a plurality of conductive interconnects 252, such as conductive posts, copper posts, conductive pillars and other, similar structures that were formed within the openings 250 in resist layer 248. In some embodiments, the conductive interconnects 252 may be formed in a periphery of the semiconductor assembly 300. The conductive interconnects 252 can be formed as columns, pillars, posts, bumps, or studs that are formed of copper or other suitable conductive material. Conductive interconnects 252 can be formed using patterning and metal deposition processes such as printing, PVD, CVD, sputtering, electrolytic plating, electroless plating, metal evaporation, metal sputtering, or other suitable metal deposition process. When conductive interconnects 252 are formed by plating, the seed layer 190 can be used as part of the plating process. Conductive interconnects 252 can be one or more layers of Al, Cu, Sn, Ni, Au, Ag, Pd, solder, or other suitable electrically conductive material and can include one or more layers.

After formation of the conductive interconnects 252, the resist layer 248 can be removed, such as by a stripping process, leaving conductive interconnects 252 in the peripheral area 143 around the semiconductor die mounting sites 142 to provide for subsequent vertical or three dimensional (3D) electrical interconnection for the fully-molded bridge interposer 300. Conductive interconnects 252 can include a height H2 in a range of 80-300 μm or a height in a range of 100-150 μm, or a height thereabout. In other instances, conductive vertical interconnects 252 may include a height in a range of 10-600 μm, 60-100 μm, 70-90 μm, or about, 80 μm. As used herein, “thereabout,” “about,” or “substantially” means a percent difference in a range of 0-5%, 1-10%, 1-20%, 1-30%, or 1-40% of the number or range indicated.

After removal of the resist layer 248, the component mounting sites 142 on or over the temporary carrier 140, the build-up interconnect structure 170, or both, can be exposed and ready to receive the component 114. The orientation of component 114 can be either face up with front surface 121 (or active surface 120 in the instance where component 114 comprises a semiconductor die) oriented away from the temporary carrier 140 to which the component 114 are mounted, or alternatively can be mounted face down with the front surface 121 (or active surface 120) oriented toward the temporary carrier 140 to which the component 114 are mounted. After mounting the component 114 to the temporary carrier 140 in a face up orientation, the DAF 130 can undergo a curing process to cure the DAF 130 and to lock the component 114 in place to the build-up interconnect structure 170 and over the temporary carrier 140.

FIG. 4E shows a top or plan view of a portion of the temporary carrier 140 and the conductive interconnects 252 taken along the section line 4E from FIG. 4D. FIG. 4E shows that the conductive interconnects 252 can be formed within, and extend intermittently across, the peripheral area 143 and surround the component mounting sites 142 (and the component 114) without being formed within the component mounting sites 142. Additionally, FIG. 4E shows that after the component 114 is mounted at the mounting site 142, a first side 114a of component 114 is offset by an offset O₁ from the conductive posts 252 adjacent the first side 114a. A second side 114b of component 114 (which is opposite the first side 114a) is offset by an offset O₂ from the conductive interconnects 252 adjacent the first side 114b.

FIG. 4F, continuing from FIGS. 4D and 4E, illustrates that after mounting the components 114 to the carrier 140, an encapsulant 256, such as a mold compound, a polymer composite material, such as epoxy resin with filler, epoxy acrylate with filler, PBO, polyimide, polymer with or without proper filler, and similar materials, can be deposited around the components 114 using a paste printing, compression molding, transfer molding, liquid encapsulant molding, lamination, vacuum lamination, spin coating, or other suitable applicator. Component 114 can be embedded in encapsulant 256, which can be non-conductive and environmentally protect the component 114 from external elements and contaminants. The encapsulant 256 can be formed as a single encapsulant in a single step adjacent to and directly contacting all lateral sides of the component (such as four lateral sides of the component 114), as well as be formed over the front surface 121 (and over active surface 120 where component 114 comprises an active semiconductor device) of the component 114 such that encapsulant 256 is disposed on five sides of the component 114. The same single encapsulant 256 can also be formed around and directly contact the sides of the conductive bumps 128 and the sides 252a of conductive interconnects 252 in a single step to form at least part of a molded bridge interposer panel or molded panel 258. The molded bridge interposer panel or molded panel 258 may comprise one build-up interconnect structure 170, as shown in FIG. 4F, or may comprise two opposing build-up interconnect structures 170, 270, as illustrated in FIG. 4G. While a method is shown of forming build-up interconnect structure 170 first, followed by building build-up interconnect structure 270, the order may be reversed. In some instances, the encapsulation and frontside build-up interconnect structure 270 may be built first, followed by removal of the temporary carrier 140, and further followed by the formation of the backside build-up interconnect structure 170.

The molded panel 258 can optionally undergo a curing process or post mold cure (PMC) to cure the encapsulant 256. In some instances, a top surface 262, such as a front surface and first surface of the encapsulant 256 can be substantially coplanar with first ends 253 of the conductive interconnects 252. Alternatively, the top surface 262 of the encapsulant 256 can be over, offset, or vertically separated from the first ends 253 of the conductive interconnects 252, such that the first ends 253 of the conductive interconnects 252 are exposed with respect to the encapsulant 256 after the reconstituted wafer 258 undergoes a grinding operation, or through a recess 257 in the encapsulant 256 to expose the first ends 253.

The molded panel 258 can also undergo an optional grinding operation with grinder 264 to planarize the top surface, front surface, or first surface 268 of the molded panel 258 and to reduce a thickness of the molded panel 258. The optional grinding operation also serves to planarize the top surface 262 of the encapsulant 256. The top surface 268 of the molded panel 258 after grinding or planarization can comprise one or more of the top surface 262 of the encapsulant 256, the first ends 253 of the conductive interconnects 252, and planarized tops 128t of conductive bumps 128. A chemical etch can also be used to remove and planarize the encapsulant 256 and the molded panel 258. Thus, the first ends 253 of conductive interconnects 252 can be exposed by grinding or planarization with respect to encapsulant 256 in the peripheral area 143 to provide for electrical connection between component 114 and a subsequently formed redistribution layer or build-up interconnect structure 270.

The reconstituted wafer 258 can also undergo a panel trim or trimming to remove excess encapsulant 256 that has remained in undesirable locations as a result of a molding process, such as eliminating a flange present for a mold chase. The molded panel 258 can include a footprint or form factor of any shape and size including a circular, rectangular, or square shape, the reconstituted wafer 258 comprising a diameter, length, or width of, or about, 200 millimeter (mm), 300 mm, or any other desirable size.

FIG. 4F also shows that actual positions of the component 114 within the molded panel 258 may be measured with an inspection device or optical inspection device 259. As such, subsequent processing of the fully molded panel 258 as shown and described with respect to subsequent FIGs. can be performed with respect to the actual positions of the component 114 within the molded panel 258.

Similar to or the same as shown and described for build-up interconnect structure 170 of FIG. 4A, FIG. 4G, shows forming a build-up interconnect structure 270—such as a second, a frontside, or active side build-up interconnect structure—over the molded panel 258 to electrically connect, and provide routing between, conductive interconnects 252 and the conductive bumps 128, and in some embodiments to provide routing between other devices mounted on, or coupled with, the fully-molded bridge interposer 300. While the build-up interconnect structure 270 is shown comprising three conductive layers and three insulating layers, a person of ordinary skill in the art will appreciate that fewer layers or more layers can be used depending on the configuration and design of the fully-molded bridge interposer 300. The build-up interconnect structure 270 can comprise a first insulating layer 272, such as a passivation layer, a dielectric layer, and layers made of similar materials formed or disposed over the molded panel 258. The first insulating layer 272 can comprise one or more layers of SiO₂, Si₃N₄, SiON, Ta₂O₅, Al₂O₃, polymer, polyimide, BCB, PBO, or other material having similar insulating and structural properties. The first insulating layer 272 can be formed using PVD, CVD, printing, spin coating, spray coating, sintering or thermal oxidation. Openings, which may be filled by first level conductive vias 274v can be formed through the insulating layer 272 over the conductive interconnects 252 and the conductive bumps 128 to connect with the component 114 and the conductive interconnects 252. In some embodiments, first conductive layer 274 of build-up interconnect structure 270 may comprise first pads at a first pitch P1 (as shown in FIG. 4F) within a footprint of the component 114 (e.g. 80 μm or less), and second pads at a second pitch P2 outside a footprint of the component 114 (e.g. 80 μm or more).

A first conductive layer 274 can be formed over the molded panel 258 and over the first insulating layer 272 as a first RDL layer to extend through openings in the first insulating layer 272, to electrically connect with the first level conductive vias 274v, and to electrically connect with the conductive bumps 128 and the conductive interconnects 252. As used herein, the term RDL includes distribution, redistribution, or movement, of signal through the conductive material in a vertical direction, horizontal direction, or both. As such, an RDL may, but need not have, a horizontal component. Conductive layer 274 can be one or more layers of Al, Cu, Sn, Ni, Au, Ag, or other suitable electrically conductive material formed using a patterning and metal deposition process such as sputtering, electrolytic plating, and electroless plating, or other suitable process. First level conductive vias 274v may comprise similar materials formed in a similar manner as that of conductive layer 274.

When the first conductive layer 274 is formed, it may be formed at least partially within, or as part of, a corresponding first via layer formed within the first insulating layer 272 of the frontside build-up interconnect structure 270. The first conductive layer 274 may comprise vias 274v aligned to centers 128c of the copper studs 128. The alignment with the centers 128c of studs or conductive bumps 128 may be measured with an r² (or R-squared) value for a lot (or statistically significant number) of components 114 or devices 300. The R-squared value (also known as the coefficient of correlation) is a statistical measure of how closely data is fitted to a regression line, which in this case is based on the lot of components 114 or devices 300. Stated another way, an R-squared value is the proportion of the variation in the dependent variable that is predictable from the independent variable. The alignment of first level conductive vias 274v with the centers 128c of studs or conductive bumps 128 (as shown in FIG. 4G) may have an r² value greater than or equal to 0.5, 0.6, 0.7, 0.8, or in a range greater than or equal to 0.5-0.8 relative to a difference between an offset O₁ between a first side 114a of the component 114 and a copper post 252a adjacent the first side 114a of the component 114 and a second offset O₂ between a second side 114b of the component 114 opposite the first side 114a of the components 114 and a corresponding copper post 252b adjacent the second side 114b of the component 114. As such, the r² value of greater than about 0.5 (or 50%), 0.6 (or 60%), 0.7 (or 70%), 0.8 (or (0%), or more between the centers 128c and the centers of the vias 274v of the conductive layer 274 when compared with the difference in the offsets between O₁ and O₂ provides a structural way of identifying that the processing of the build-up interconnect structure 270 was performed with respect to the actual positions of the component 114 within the molded panel 258, thereby allowing for finer pitch connections with the high density and ultra-high density interconnection with the component 114 and the build-up interconnect structure 270. Stated another way, the differences, offsets, or misalignments between the centers 128c and the centers of the vias 274v of the conductive layer 274 is less than (or more closely aligned), than the differences, offsets, or misalignments between the differences in offsets O₁ and O₂ between the copper posts 252 of the component 114 for the lot of components 114 or devices 300. Stated yet another way, for a lot of components 114 or devices 300, the differences, offsets, or misalignments between the centers 128c and the centers of the vias 274v is not statistically correlated (or has an r² value less than 0.5) to the alignment of the die to the copper posts 252 on each side of the component 114 (measured by looking at the offsets O₁ and O₂).

A second insulating layer 276, which can be similar or identical to the first insulating layer 272, can be disposed or formed over the molded panel 258, the first conductive layer 274, and the first insulating layer 272. An opening can be formed through the second insulating layer 276, and second level conductive vias 278v formed therein to electrically connect with the first conductive layer 274.

A second conductive layer 278, when desirable and when present, may be similar or identical to the first conductive layer 274, and can be formed as a second RDL layer over molded panel 258, over the first insulating layer 272, over the first conductive layer 274, over the second level conductive vias 278v, and within an opening of the second insulating layer 272, to electrically connect with the first conductive layer 274, the first level and second level conductive vias 274v, 278v, conductive interconnects 252, and the components 114.

A third insulating layer 280, when desirable and when present, may be similar or identical to the first insulating layer 272, can be disposed or formed over the second conductive layer 278 and the second insulating layer 276. An opening can also be formed in or through the third insulating layer 280 and third level conductive vias 282v formed therein to electrically connect with the second conductive layer 278.

A third conductive layer 282, when desirable and when present, may be similar or identical to the second conductive layer 278, can be formed as a third RDL layer, and comprising vias or third level conductive vias 282v disposed over and (or) through the third insulating layer 280, and be further disposed over the second insulating layer 276, over the second conductive layer 278, over the second level conductive via 278v, and within an opening of the third insulating layer 280. The third conductive layer 282 can electrically connect with the second conductive layer 278, and be coupled with the conductive interconnects 252 and the components 114.

In some instances, the third (or final) conductive layer 282 within the build-up interconnect structure 270 can be formed as UBMs that are formed over the third insulating layer 280 to electrically connect with the other conductive layers and conductive vias within the build-up interconnect structure 270, as well as electrically connect to the component 114, the conductive bumps 128, and the conductive interconnects 252. The UBMs as part of third conductive layer 282 (and UBMs as part of first conductive layer 174), like all of the layers, plating layers, or conductive layers formed by a plating process as presented herein, can be a multiple metal stack comprising one or more of an adhesion layer, barrier layer, seed layer, or wetting layer. The adhesion layer can comprise titanium (Ti), or titanium nitride (TiN), titanium tungsten (TiW), Al, or chromium (Cr). The barrier layer can be formed over the adhesion layer and can be made of Ni, NiV, platinum (Pt), palladium (Pd), TiW, or chromium copper (CrCu). In some instances, the barrier layer can be a sputtered layer of TiW or Ti and can serve as both the adhesion layer and the barrier layer. In either event, the barrier layer can inhibit unwanted diffusion of material, like Cu. The seed layer can be Cu, Ni, NiV, Au, Al, or other suitable material. For example, the seed layer can be a sputtered layer of Cu comprising a thickness of about 2000 angstroms (e.g., 2000 plus or minus 0-600 angstroms). The seed layer can be formed over the barrier layer and can act as an intermediate conductive layer below subsequently formed upper bumps, balls, or interconnect structures 290. In some instances, the wetting layer can comprise a layer of Cu with a thickness in a range of about 5-11 μm or 7-9 μm. Upper bumps 290, such as when formed of SnAg solder, can consume some of the Cu UBM during reflow and forms an intermetallic compound at the interface between the solder bump 290 and the Cu of the wetting layer. However, the Cu of the wetting layer can be made thick enough to prevent full consumption of the Cu pad by the solder during high temperature aging.

UBMs 282 may be formed as a POP UBM pad, UBM structure, or land pad, such as for stacked POP structure, an additional electronic component. In some instances, the UBMs 282 can comprise Ni, Pd and Au. UBMs 282 can provide a low resistive interconnect to build-up interconnect structure 270 as well as a barrier to solder diffusion and seed layer for solder wettability.

The upper bumps 290 can be formed on or coupled to the UBMs 282. The bumps 290 can be formed by depositing an electrically conductive bump material over the UBMs 282 using an evaporation, electrolytic plating, electroless plating, ball drop, or screen-printing process. The bump material can be Al, Sn, Ni, Au, Ag, Pb, bismuth (Bi), Cu, solder, and combinations thereof, with an optional flux solution. For example, the bump material can be eutectic Sn/Pb, high-lead solder, or lead-free solder. The bump material can be bonded to the UBMs 282 using a suitable attachment or bonding process. In one embodiment, the bump material is reflowed by heating the material above its melting point to form spherical balls or bumps 290. In some applications, bumps 290 are reflowed a second time to improve electrical contact to UBMs 282. The bumps 290 can also be compression bonded or thermocompression bonded to the UBMs 282. Bumps 290 represent one type of interconnect structure that can be formed over the conductive interconnects 252, and other desirable structures, such as conductive paste, stud bump, micro bump, or other electrical interconnects may also be used as desired.

FIG. 4H illustrates singulation of the molded panel 258 and build-up interconnect structures 170, 270 with saw blade or laser cutting tool 294 to form individual fully-molded bridge interposers 300. The final interposer structure 300 may be thinner than previous packages, comprising an overall height or thickness of, or on the order of, or about, 50-250, 100-200, or less than or about 150 μm. Stacks of multiple layers can be correspondingly thicker, and increase in multiples of the above ranges, resulting in an overall thickness in a range of 200-1,000 μm. As part of the reduced height of the structure, the final structure may be made without an interposer, comprising the build-up interconnect layers and conductive interconnects providing the function of a conventional interposer.

The carrier 140 in any of the embodiments disclosed herein, can be removed, e.g., by grinding the carrier 140, by exposing UV release tape 144 to UV radiation separate the UV tape 144 from the glass substrate 140, by thermal release, or other suitable method. After removal of the carrier 140, the molded panel 258 can also undergo an etching process, such as a wet etch, to clean the surface of the molded panel 258 exposed by removal of the temporary carrier 140, such as any exposed first or second ends 253, 254 of conductive interconnect 252, for subsequent connection of bumps, balls or interconnect structure 290 and tops of conductive bumps 128 after planarizing, as part of build-up interconnect structures 170, 270. The exposed first and (or) second ends 253, 254 of the conductive interconnects 252 can also undergo a coating or pad finishing process, such as by an Organic Solderability Preservative (OSP) coating, solder printing, electroless plating, or other suitable process, to form a PoP UBM pad, UBM structures, land pads, BGA pads, or other suitable structures, as desired.

Bumps 296, such as lower bumps, balls, or interconnect structures, can be formed on or coupled through either or both of build-up interconnect structures 170, 270, to either or both of the exposed first and second ends 253, 254 of the conductive interconnects 252, as shown, for example, in FIG. 5C. The bumps 296 can be formed by depositing an electrically conductive bump material over pads on build-up interconnect structures 170, 270, coupled to the exposed second ends 254 of the conductive interconnects 252 using an evaporation, electrolytic plating, electroless plating, ball drop, or screen-printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material can be bonded to the pads on build-up interconnect structures 170, 270 coupled to either or both of exposed first and second ends 253, 254 of the conductive interconnects 252 using a suitable attachment or bonding process. In one embodiment, the bump material is reflowed by heating the material above its melting point to form spherical balls or bumps 296. In some applications, bumps 296 are reflowed a second time to improve electrical contact to conductive interconnects 252. The bumps 296 can also be compression bonded or thermocompression bonded to the conductive interconnects 252. Bumps 296 represent one type of interconnect structure that can be formed over the conductive interconnects 252, and other desirable structures, such as conductive paste, stud bump, micro bump, or other electrical interconnects may also be used as desired.

Similar to as shown and described for FIG. 4H, FIG. 4I illustrates singulation of a molded panel 258 and build-up interconnect structures 170, 270 with saw blade or laser cutting tool 294 to form individual, fully-molded bridge interposers 302, such as a component interposer, component device, semiconductor device, semiconductor assembly, and other, similar structures. The fully-molded bridge interposer 302 comprises one or more components 117 as shown in FIG. 3E, such as a semiconductor die, embedded devices, a bridge die, and other, similar components, having conductive layers and insulating layers disposed thereon.

Similar to as shown and described for FIG. 4I, FIG. 4J illustrates singulation of a molded panel 258 and build-up interconnect structures 170, 270 with saw blade or laser cutting tool 294 to form individual, fully-molded bridge interposers 304, such as a component interposer, component device, semiconductor device, semiconductor assembly, and other, similar structures. The fully-molded bridge interposer 304 comprises one or more components 117a as shown in FIG. 3F, such as a semiconductor die, embedded devices, a bridge die, and other, similar components, having one or more conductive layers and insulating layers disposed thereon, and having one or more planarization layers interleaved between the conductive layers and insulating layers.

The use of components 117, 117a provides for increased interconnection density through the use of additional dielectric layers and conductive layers. Finer or smaller pitch and reduced manufacturing defects may be achieved through incorporation of one or more planarization layers interleaved between the dielectric and conductive layers.

FIG. 5A illustrates a high-level perspective view of a fully molded bridge interposer 300 disposed (or sandwiched) between: (i) a chiplet arrangement 310 of semiconductor devices (e.g., a System On Chip (SOC) 312 and High Bandwidth Memory (HBM) devices 314), and (ii) a substrate or package substrate 320, similar to what was shown in FIGS. 2A-2C. In the past, a chiplet 60 or arrangement of semiconductor devices 62, 64 similar to what was shown in FIG. 2A may have been coupled together with silicon interposers comprising TSVS, or EMIBs, as shown and described above with respect to FIGS. 1A-IF. However, FIGS. 5A-5E show the new technology of a fully molded bridge interposer 300 to replace the existing technology of a silicon interposer or EMIB.

FIG. 5B shows a cross-sectional profile view taken along the section-line or box labeled “5B” in FIG. 5A. FIG. 5B shows a cross-sectional profile view of the fully-molded bridge interposer 300, similar to the view shown in FIG. 4H. Moreover, the view of FIG. 5B further includes the features of the fully-molded bridge interposer 300 shown more closely to scale. FIG. 5B shows the peripheral conductive interconnect structures 252 disposed around, and laterally offset from, the component 114 and within the encapsulant material 256. The peripheral conductive interconnect structures 252 can extend completely through the encapsulant 256 in a vertical direction from, or adjacent, the top surface 262 of the encapsulant 256 to, or adjacent, the bottom surface 266 of the encapsulant 256 opposite top surface 262 to provide vertical electrical interconnection through the fully-molded bridge interposer 300, which can facilitate stacking of packages in PoP arrangements. FIG. 5B further shows a fully molded bridge interposer 300 disposed between a chiplet arrangement 310 of at least two semiconductor devices (such as a SOC 312 and a HBM 314) and a package substrate 320.

FIG. 5C shows a close-up sectional profile view of a portion of the fully molded bridge interposer 300 of FIG. 5B shown within the section-line or box designated 5C. FIG. 5C shows the component 114, conductive or copper bumps or interconnects 128, and conductive or copper posts 252, included within the encapsulant 256. Electrical build-up interconnect structures 170, 270 comprising RDLs are formed above and below opposing surfaces 262, 266 of the encapsulant 256 as well as above and below the component 114 and conductive or copper studs 128, and conductive or copper posts 252. In some embodiments of the molded bridge interposer 300, build-up interconnect structure 170 may comprise first conductive layer 174, comprising first level conductive vias 174v coupled to bumps 296. The component 114, conductive or copper studs 128, and conductive or copper posts 252, are electrically coupled to, or interconnected with, the chiplet arrangement 310, which may include a SOC 312, HBMs 314, and any other number of desired semiconductor devices within the chiplet 310 or SOC 312.

Attachment options for the molded bridge interposer 300, to chiplet arrangement 310 include upper bumps, balls, or interconnect structures 290. Attachment options for the molded bridge interposer 300 to the substrate 320 include lower bumps 296, such as balls, or interconnect structures. Bumps 290 and 296 may each include: 1) solder bumps, 2) plated copper plus a solder post, and 3) direct copper to copper bonding. Additional design options for the fully molded bridge interposer 300 include: 1) underfill, and 2) over mold, as desired or as applicable.

FIG. 5C also shows exemplary layers labeled with dimensions that are about, or approximately, the dimensions indicated. The component 114 may comprise a height or thickness (with or without ta die attach material 115) of about 100 μm and the conductive posts 252 may comprise a height of about 125 μm. As used herein “about” and “approximately” mean within a percent difference of less than or equal to 40%, 30%, 20%, 10%, 5%, 3%, 2%, or 1%.

FIGS. 5D and 5E show close-up sectional profile views of a portion of the fully molded bridge interposers 302, 304 of FIG. 5B shown within the section-line or box designated 5D, 5E. FIG. 5D depicts a detail view of component 117 comprising additional conductive layers and insulating layers disposed thereon. FIG. 5E illustrates a detail view of component 117a comprising planarization layers 160 interleaved with additional RDL and conductive layers.

The fully-molded bridge interposers 300, 302, 304 provide cost advantages for high density integration, which includes integrations comprising 2 μm line and space pitch, and 20 μm area array bond pad pitch. Advantages include: (i) cost reduction greater than or equal to 80% for extending die size with respect to growing monolithic silicon (e.g., $0.01 per mm² versus $0.06 per mm²), and (ii) cost reduction greater than or equal to 50% compared to laminate embedded bridges (e.g., $0.01 per mm² vs. $0.03 per mm². For ultra-high density integration with the fully molded bridge interposer 300, an enabled 20 μm area array bond pad pitch allows for increased or improved input/output (IO) on advanced node silicon without a die size penalty so that the integrated circuit (IC) device IO count is no longer constrained by a number of bond pads which will fit in minimum possible device size. As such, as much as an 80% reduction in die size is possible when total size has been based bond pad area requirements when using existing technology.

While this disclosure includes a number of embodiments in different forms, the drawings and written descriptions present detail of particular embodiments with the understanding that the present disclosure is to be considered as an exemplification of the principles of the disclosed methods and systems, and is not intended to limit the broad aspect of the disclosed concepts to the embodiments illustrated. Additionally, it should be understood by those of ordinary skill in the art that other manufacturing devices and examples could be intermixed or substituted with those provided. In places where the description above refers to particular embodiments, it should be readily apparent that a number of modifications may be made without departing from the spirit thereof and that these embodiments and implementations may be applied to other technologies as well. Accordingly, the disclosed subject matter is intended to embrace all such alterations, modifications and variations that fall within the spirit and scope of the disclosure and the knowledge of one of ordinary skill in the art.

What is claimed is:

1. A semiconductor assembly, comprising:
a bridge component comprising conductive studs disposed over a frontside, a backside opposite the conductive studs, and no vias formed through the bridge component, wherein:
the bridge component comprises one or more interconnect layers disposed over the frontside and an outermost interconnect layer is coupled to the conductive studs;
conductive vertical interconnects formed as copper posts disposed in a periphery of the semiconductor assembly;
an encapsulant disposed on five sides of the bridge component, on sides of the conductive studs, and on sides of the copper posts that leave ends of the conductive studs and opposing first and second ends of the copper posts coplanar with top and bottom surfaces of the encapsulant, wherein the encapsulant is not disposed over the backside of the bridge component; and
a frontside build-up interconnect structure over the conductive studs of the bridge component and coupled to first ends of the copper posts opposite the second ends of the copper posts, the frontside build-up interconnect structure comprising first pads at a first pitch within a footprint of the bridge component of less than or equal to 80 μm and second pads at a second pitch outside a footprint of the bridge component of greater than or equal to the first pitch.

2. The semiconductor assembly of claim 1, wherein the bridge component comprises one or more of an active device and a passive device.

3. The semiconductor assembly of claim 1, wherein the bridge component further comprises one or more planarization layers disposed between two or more interconnect layers.

4. The semiconductor assembly of claim 3, wherein the bridge component comprises up to and including eight bridge component build-up interconnect structures and one or more planarization layers disposed between the bridge component build-up interconnect structures.

5. The semiconductor assembly of claim 1, further comprising a misalignment of the bridge component with respect to an assembly edge is greater than a misalignment of an under bump metallization (UBM) with respect to the assembly edge.

6. The semiconductor assembly of claim 1, further comprising a backside build-up interconnect structure formed over a backside of the bridge component and coupled to first ends of the copper posts.

7. The semiconductor assembly of claim 1, wherein:
the semiconductor assembly further comprises a total thickness less than or equal to 150 μm; and
the semiconductor assembly is disposed over, and is coupled to, a package substrate, a printed circuit board (PCB), a multilayer ceramic capacitors (MLCC), or a passive device.

8. A semiconductor assembly, comprising:
a bridge component formed without vias extending through the bridge component, and comprising conductive studs, wherein:
the bridge component comprises one or more interconnect layers disposed over a frontside of the bridge component and an outermost interconnect layer is coupled to the conductive studs;
conductive vertical interconnects disposed in a periphery of the semiconductor assembly;
an encapsulant disposed on five sides of the bridge component, on sides of the conductive studs, and on sides of the conductive vertical interconnects that leave ends of the conductive studs and opposing first and second ends of the conductive vertical interconnects coplanar with top and bottom surfaces of the encapsulant; and
a frontside build-up interconnect structure over the conductive studs of the bridge component and coupled to first ends of the conductive vertical interconnects opposite the second ends of the conductive vertical interconnects, the frontside build-up interconnect structure comprising first pads at a first pitch within a footprint of the bridge component and second pads at a second pitch outside a footprint of the bridge component.

9. The semiconductor assembly of claim 8, wherein the bridge component comprises one or more of an active device and a passive device.

10. The semiconductor assembly of claim 8, wherein the bridge component further comprises one or more planarization layers disposed between two or more bridge component interconnect layers.

11. The semiconductor assembly of claim 10, wherein the bridge component comprises up to and including eight bridge component interconnect layers and one or more planarization layers disposed between the bridge component interconnect layers.

12. The semiconductor assembly of claim 8, further comprising a misalignment of the bridge component with respect to an assembly edge is greater than a misalignment of an under bump metallization (UBM) with respect to the assembly edge.

13. The semiconductor assembly of claim 8, further comprising:
a first component comprising a system on chip (SOC) integrated circuit, memory controller or high bandwidth memory (HBM) controller, voltage regulator, a serializer/deserializer (SERDES), or active semiconductor die, the first component comprising high density interconnects coupled with the first pads, and low density interconnects coupled with the second pads; and
a second component comprising a SOC integrated circuit, memory controller or HBM controller, voltage regulator, a SERDES, or active semiconductor die, the second component comprising, high density interconnects coupled with the first pads, and low density interconnects coupled with the second pads.

14. The semiconductor assembly of claim 8, wherein the first pitch within a footprint of the bridge component is less than or equal to 80 μm and the second pitch outside a footprint of the bridge component is greater than or equal to the first pitch.

15. The semiconductor assembly of claim 8, wherein:
the semiconductor assembly further comprises a total thickness less than or equal to 150 μm; and
the semiconductor assembly is disposed over, and is coupled to, a package substrate, a printed circuit board (PCB), a multilayer ceramic capacitors (MLCC), or a passive device.

16. A method of making a semiconductor assembly, comprising:
providing a temporary carrier;
disposing conductive vertical interconnects in a periphery of a bridge component site;
disposing a bridge component over the temporary carrier and within the bridge component site, wherein the bridge component comprises one or more interconnect layers disposed over a frontside and an outermost interconnect layer comprises a plurality of conductive studs and the bridge component does not comprise vias through the bridge component;
forming an encapsulant disposed on five sides of the bridge component, on sides of the plurality of conductive studs, and on sides of the conductive vertical interconnects that leave ends of the plurality of conductive studs and first ends of the conductive vertical interconnects exposed from the encapsulant, wherein the bridge component, conductive vertical interconnects, and encapsulant together form a molded bridge interposer; and
forming a frontside build-up interconnect structure over the plurality of conductive studs of the bridge component and coupled to first ends of the conductive vertical interconnects opposite second ends of the conductive vertical interconnects, the frontside build-up interconnect structure comprising first pads at a first pitch within a footprint of the bridge component and second pads at a second pitch outside a footprint of the bridge component.

17. The method of claim 16, further comprising:
removing at least a portion of the temporary carrier; and
removing a portion of the encapsulant from over the conductive vertical interconnects and the plurality of conductive studs.

18. The method of claim 16, wherein:
a pitch of the plurality of conductive studs comprises a pitch of less than or equal to 80 μm; and
the first pitch is less than or equal to the second pitch.

19. The method of claim 18, further comprising forming a backside build-up interconnect structure formed over the temporary carrier before disposing the bridge component over the temporary carrier and over the backside build-up interconnect structure.

20. The method of claim 16, wherein the bridge component comprises an active device or a passive component.

21. The method of claim 16, further comprising:
coupling a first component comprising a system on chip (SOC) integrated circuit, memory controller or high bandwidth memory (HBM) controller, voltage regulator, a serializer/deserializer (SERDES), or active semiconductor die to the molded bridge interposer, the first component comprising interconnects coupled with a first portion of the first pads, and lower density interconnects coupled with a first portion of the second pads; and
coupling a second component comprising a SOC integrated circuit, memory controller or HBM controller, voltage regulator, a SERDES, or active semiconductor die, the second component comprising interconnects coupled with a second portion of the first pads, and lower density interconnects coupled with a second portion of the second pads.

22. The method of claim 16, further comprising a misalignment of the bridge component with respect to an assembly edge is greater than a misalignment of an under bump metallization (UBM) with respect to the assembly edge.

23. The method of claim 16, further comprising forming the frontside build-up interconnect structure using unit specific patterning.

24. The method of claim 16, wherein the bridge component further comprises one or more planarization layers disposed between two or more interconnect layers.

25. The method of claim 24, wherein the bridge component comprises up to and including 8 interconnect layers and one or more planarization layers disposed between the one or more interconnect layers.
